(19) United States
(12) Patent Application Publication
(10) Pub. No.: US 2025/0133910 A1
(43) Pub. Date: Apr. 24, 2025

(54) Display Panel and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Longfeng Jiang, Beijing (CN); Kening Zheng, Beijing (CN); Changlong Yuan, Beijing (CN); Zhenhua Zhang, Beijing (CN); Dengyu Wang, Beijing (CN)

(21) Appl. No.: 18/691,579

(22) PCT Filed: Sep. 7, 2022
(86) PCT No.: PCT/CN2022/117587

§ 371 Date: Mar. 13, 2024

(51) Int. Cl. H10K 59/122; H10K 59/123; H10K 59/13; H10K 59/131; H10K 59/80

(52) U.S. Cl. CPC H10K 59/122; H10K 59/123; H10K 59/13; H10K 59/131; H10K 59/8792

(57) ABSTRACT

A display panel includes a substrate, a first electrode layer, a pixel definition layer, light-emitting patterns, light-absorbing pattern(s) and a second electrode layer. The first electrode layer includes first anodes and at least one second anode. The pixel definition layer is provided with first openings and at least one second opening therein. A first opening corresponds in position to the first anode, and a second opening corresponds in position to the second anode. At least portion of a light-emitting pattern is located in the first opening. At least portion of a light-absorbing pattern is located in the second opening. The second electrode layer covers the light-emitting patterns and the light-absorbing pattern(s). The display panel includes a plurality of sub-pixels and at least one photosensor, and each photosensor is arranged adjacent to at least one sub-pixel. A sub-pixel includes the light-emitting pattern, and a photosensor include the light-absorbing pattern.

### CROSS-REFERENCE TO RELATED APPLICATION

This application is the United States national phase of International Patent Application No. PCT/CN2022/117587, filed Sep. 7, 2022, the disclosure of which is hereby incorporated by reference in its entirety.

### BACKGROUND OF THE INVENTION

### Field of the Invention

The present disclosure relates to the field of display technologies, and in particular, to a display panel and a display apparatus.

### Description of Related Art

Fingerprint recognition technology refers to a technology that can obtain fingerprint information by sensing and analyzing signals of valleys and ridges of a fingerprint through a fingerprint recognition module, which has many advantages such as high safety, easy and fast operation, and therefore widely used in electronic products. Fingerprint imaging may be realized through a variety of technologies such as optical imaging, capacitive imaging, ultrasonic imaging, in which the optical fingerprint recognition technology has gradually become the mainstream of fingerprint recognition technology due to its characteristics such as strong penetration ability, support for full-screen arrangement and simple product structure design, and therefore is widely used in the electronic products.

At present, the optical fingerprint sensor in the display apparatus is provided under the screen, i.e., disposed on the non-display side of the display panel. The fingerprint recognition process of the under-screen optical fingerprint sensor is as follows: light emitted by the display panel is irradiated onto a finger on the display side of the display panel, and the light is reflected by the finger to form return light carrying fingerprint information, and the return light passes through the display panel and is irradiated onto the under-screen optical fingerprint sensor to perform the fingerprint recognition detection.

### SUMMARY OF THE INVENTION

In an aspect, a display panel is provided. The display panel includes a substrate, a first electrode layer, a pixel definition layer, light-emitting patterns, at least one light-absorbing pattern and a second electrode layer.

The first electrode layer is disposed on a side of the substrate; the first electrode layer includes first anodes and at least one second anode, and a first anode and a second anode are configured to respectively transmit different anode signals. The pixel definition layer is disposed on a side of the first electrode layer away from the substrate; the pixel definition layer is provided with first openings and at least one second opening therein, and a first opening corresponds in position to the first anode, and a second opening corresponds in position to the second anode. At least portion of a light-emitting pattern of the light-emitting patterns is located in the first opening. At least portion of a light-absorbing pattern of the at least one light-absorbing pattern is located in the second opening. The second electrode layer is disposed on a side of the pixel definition layer away from the first electrode layer and covering the light-emitting patterns and the at least one light-absorbing pattern.

The display panel includes a plurality of sub-pixels and at least one photosensor, and each photosensor is arranged adjacent to at least one sub-pixel. A sub-pixel includes the first anode, the light-emitting pattern and a portion of the second electrode layer covering the light-emitting pattern, and a photosensor of the at least one photosensor includes the second anode, the light-absorbing pattern and a portion of the second electrode layer covering the light-absorbing pattern.

In some embodiments, the light-absorbing pattern includes a plurality of light-absorbing sub-patterns that are sequentially arranged in a direction perpendicular to the substrate, and each light-absorbing sub-pattern is capable of absorbing light of at least one color.

In some embodiments, the light-absorbing pattern includes a first light-absorbing sub-pattern and a second light-absorbing sub-pattern, at least one color of light that the first light-absorbing sub-pattern is capable of absorbing is the same as at least one color of light that the second light-absorbing sub-pattern is capable of absorbing.

In some embodiments, a wavelength of the light that the first light-absorbing sub-pattern is capable of absorbing and a wavelength of the light that the second light-absorbing sub-pattern is capable of absorbing are substantially in a same range.

In some embodiments, a material of the first light-absorbing sub-pattern is the same as a material of the second light-absorbing sub-pattern.

In some embodiments, the light-absorbing pattern includes a first light-absorbing sub-pattern and a second light-absorbing sub-pattern, at least one color of light that the first light-absorbing sub-pattern is capable of absorbing is not exactly the same as at least one color of light that the second light-absorbing sub-pattern is capable of absorbing.

In some embodiments, one of the first light-absorbing sub-pattern and the second light-absorbing sub-pattern is capable of absorbing red light and blue light, and another of the first light-absorbing sub-pattern and the second light-absorbing sub-pattern is capable of absorbing green light; alternatively, one of the first light-absorbing sub-pattern and the second light-absorbing sub-pattern is capable of absorbing red light and green light, and another of the first light-absorbing sub-pattern and the second light-absorbing sub-pattern is capable of absorbing blue light; alternatively, one of the first light-absorbing sub-pattern and the second light-absorbing sub-pattern is capable of absorbing blue light and green light, and another of the first light-absorbing sub-pattern and the second light-absorbing sub-pattern is capable of absorbing red light.

In some embodiments, the display panel further includes a second heterojunction disposed between the first light-absorbing sub-pattern and the second light-absorbing sub-pattern.

In some embodiments, the light-emitting pattern includes a first light-emitting sub-pattern and a second light-emitting sub-pattern that are sequentially arranged in the direction perpendicular to the substrate. The display panel further includes a first heterojunction disposed between the first light-emitting sub-pattern and the second light-emitting sub-pattern. The first heterojunction and the second heterojunction are connected to be a one-piece structure.

In some embodiments, the light-absorbing pattern of the photosensor is capable of absorbing light of a single color. A photosensor capable of absorbing light of a target color is arranged adjacent to a sub-pixel capable of emitting light of the target color.

In some embodiments, the light-absorbing pattern of the photosensor is capable of absorbing light of two colors. A photosensor capable of absorbing light of a first target color and light of a second target color is arranged between a sub-pixel capable of emitting the light of the first target color and a sub-pixel capable of emitting the light of the second target color.

In some embodiments, the light-absorbing pattern of the photosensor is capable of absorbing light of three colors, and the light of three colors includes red light, blue light and green light. The photosensor capable of absorbing the light of three colors is arranged adjacent to a sub-pixel capable of emitting green light.

In some embodiments, the display panel includes a plurality of light-absorbing patterns. A material of the light-absorbing pattern includes a perovskite-based semiconductor material. Light-absorbing patterns capable of absorbing light of different colors correspond to materials with different band gaps.

In some embodiments, a molecular formula of the material of the light-absorbing pattern is RNH₃BY₃₋ₘXₘ, where R is CₙH₂ₙ₊₁, B is a metal element, X and Y are different halogen elements, and m and n are both an integer. The materials corresponding to the light-absorbing patterns capable of absorbing the light of different colors have different mass ratios of X and Y.

In some embodiments, the display panel further includes a first light-shielding pattern and a cover plate. The first light-shielding pattern is disposed on a side of the second electrode layer away from the substrate; the first light-shielding pattern is provided with a third opening and a fourth opening therein, the third opening is disposed corresponding to the light-emitting pattern, and the fourth opening is disposed corresponding to the light-absorbing pattern. The cover plate is disposed on a side of the first light-shielding pattern away from the substrate.

A ratio of a vertical distance from a surface of the first light-shielding pattern away from the substrate to a surface of the cover plate away from the substrate to a vertical distance from the surface of the first light-shielding pattern away from the substrate to the light-absorbing pattern is in a range of approximately 1.8 to approximately 2.8.

In some embodiments, a minimum included angle between a connection line, between a side wall of the fourth opening and the light-absorbing pattern corresponding to the fourth opening, and the light-absorbing pattern is in a range of approximately 40° to approximately 60°.

In some embodiments, the display panel further includes a second light-shielding pattern disposed between the substrate and the second electrode layer. The second light-shielding pattern is located between the light-absorbing pattern and a light-emitting pattern adjacent to the light-absorbing pattern, and a vertical distance from a surface of the second light-shielding pattern away from the substrate to the substrate is greater than or equal to both a vertical distance from a surface of the light-absorbing pattern away from the substrate to the substrate and a vertical distance from a surface of the light-emitting pattern away from the substrate to the substrate.

In some embodiments, a ratio of an area of the first opening to an area of the second opening is in a range of approximately 1 to approximately 3.5.

In some embodiments, the display substrate further includes an encapsulation layer disposed on a side of the second electrode layer away from the substrate. A refractive index of the encapsulation layer is in a range of 1.5 to 1.8.

In some embodiments, the display panel further includes a driving signal line, an end of the driving signal line is electrically connected to the second anode, and another end of the driving signal line is electrically connected to an external processor. The driving signal line is configured to transmit a second anode signal to the second anode.

In some embodiments, the display panel further includes a circuit layer disposed between the substrate and the first electrode layer. The circuit layer includes pixel circuits and at least one photosensitive driving circuit, a pixel circuit is electrically connected to the first anode, and a photosensitive driving circuit is connected to the second anode.

In some embodiments, the circuit layer includes an active layer, a gate insulating layer, a gate conductive layer, an interlayer dielectric layer, and a source-drain conductive layer that are arranged in a direction perpendicular to the substrate and away from the substrate.

The pixel circuit includes a first active layer pattern, a scan signal line and a first power supply line, the first active layer pattern is located in the active layer, the scan signal line is located in the gate conductive layer, and the first power supply line is located in the source-drain conductive layer; the pixel circuit includes at least one transistor, overlapping portions of the first active layer pattern and the scan signal line form a part of a transistor, and the at least one transistor is electrically connected to the first anode; the first power supply line is electrically connected to the at least one transistor.

In some embodiments, the photosensitive driving circuit includes a diode and a second power supply line. The second power supply line is located in the source-drain conductive layer; an end of the diode is electrically connected to the second anode, and another end of diode is electrically connected to the second power supply line.

In some embodiments, the diode includes a second active layer pattern, and the second active layer pattern is located in the active layer. The second active layer pattern includes a first portion and a second portion that are electrically connected, the first portion is a hole-type semiconductor, and the second portion is an electron-type semiconductor; the first portion is electrically connected to the second anode, and the second portion is electrically connected to the second power supply line.

In some embodiments, the display panel further includes a second hole transport pattern disposed between the second anode and the light-absorbing pattern.

In some embodiments, the display panel further includes a first hole transport pattern disposed between the first anode and the light-emitting pattern. A material of the first hole transport pattern is different from a material of the second hole transport pattern.

In some embodiments, the display panel further includes a first common layer and/or a second common layer. The first common layer is disposed between the first anode and the light-emitting pattern and between the second anode and the light-absorbing pattern; the first common layer includes a hole transport layer and/or a hole injection layer. The second common layer is disposed between the light-emitting pattern and the second electrode layer and between the light-absorbing pattern and the second electrode layer; the second common layer includes an electron transport layer and/or an electron injection layer.

In some embodiments, the second electrode layer includes first cathodes and at least one second cathode, a first cathode corresponds in position to the light-emitting pattern, and a second cathode corresponds in position to the light-absorbing pattern. The first cathode and the second cathode are in a one-piece structure; alternatively, the first cathode and the second cathode are insulated from each other, and the first cathode and the second cathode are configured to respectively transmit different cathode signals.

In some embodiments, a voltage between the first anode and the second electrode layer is in a range of 8 V to 16 V, and a voltage between the second anode and the second electrode layer is in a range of −2 V to 8 V.

In another aspect, a display panel is provided. The display panel includes a substrate, a first electrode layer, a pixel definition layer, a light-emitting pattern, a light-absorbing pattern, a second electrode layer, a first light-shielding pattern and a cover plate.

The first electrode layer is disposed on a side of the substrate; the first electrode layer includes a first anode and a second anode, and the first anode and the second anode are configured to respectively transmit different anode signals. The pixel definition layer is disposed on a side of the first electrode layer away from the substrate; the pixel definition layer is provided with a first opening and a second opening therein, and the first opening corresponds in position to the first anode, and the second opening corresponds in position to the second anode. At least portion of the light-emitting pattern is located in the first opening. At least portion of the light-absorbing pattern is located in the second opening. The second electrode layer is disposed on a side of the pixel definition layer away from the first electrode layer and covering the light-emitting pattern and the light-absorbing pattern. The first light-shielding pattern is disposed on a side of the second electrode layer away from the substrate. The cover plate is disposed on a side of the first light-shielding pattern away from the substrate.

A ratio of a vertical distance from a surface of the first light-shielding pattern away from the substrate to a surface of the cover plate away from the substrate to a vertical distance from the surface of the first light-shielding pattern away from the substrate to the light-absorbing pattern is in a range of approximately 1.8 to approximately 2.8.

In yet another aspect, a display apparatus is provided. The display apparatus includes a housing and the display panel as described in any one of the above embodiments. The housing is disposed at least partially around the display panel.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a top view of a display apparatus, in accordance with some embodiments;

FIG. 2 is an exploded view of a display apparatus, in accordance with some embodiments;

FIG. 3 is a sectional view of a display apparatus in the related art;

FIG. 4 is a top view of a display panel, in accordance with some embodiments;

FIG. 5 is a top view of another display panel, in accordance with some embodiments;

FIG. 6 is a sectional view taken along the section line B-B′ in FIG. 2;

FIG. 7 is a top view of a functional device region, in accordance with some embodiments;

FIG. 8 is a top view of another functional device region, in accordance with some embodiments;

FIG. 9 is a top view of yet another functional device region, in accordance with some embodiments;

FIG. 10 is a top view of yet another functional device region, in accordance with some embodiments;

FIG. 11 is a top view of yet another functional device region, in accordance with some embodiments;

FIG. 12 is a top view of yet another functional device region, in accordance with some embodiments;

FIG. 13 is a top view of yet another functional device region, in accordance with some embodiments;

FIG. 14 is another sectional view taken along the section line B-B′ in FIG. 2;

FIG. 15 is yet another sectional view taken along the section line B-B′ in FIG. 2;

FIG. 16 is sectional view taken along the section line B-B′ in FIG. 2;

FIG. 17 is a top view of yet another display panel, in accordance with some embodiments;

FIG. 18 is yet another sectional view taken along the section line B-B′ in FIG. 2;

FIG. 19 is yet another sectional view taken along the section line B-B′ in FIG. 2;

FIG. 20 is a top view of yet another display panel, in accordance with some embodiments;

FIG. 21 is a top view of yet another display panel, in accordance with some embodiments;

FIG. 22 is yet another sectional view taken along the section line B-B′ in FIG. 2;

FIG. 23 is yet another sectional view taken along the section line B-B′ in FIG. 2;

FIG. 24 is yet another sectional view taken along the section line B-B′ in FIG. 2;

FIG. 25 is a diagram showing a picture to be scanned, in accordance with some embodiments; and

FIG. 26 is a diagram showing an image after scanning and imaging by a display apparatus, in accordance with some embodiments.

### DESCRIPTION OF THE INVENTION

The technical solutions in some embodiments of the present disclosure will be described clearly and completely with reference to the accompanying drawings. Obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, the term such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above term do not necessarily refer to the same embodiment(s) or example(s). In addition, specific features, structures, materials or characteristics may be included in any one or more embodiments or examples in any suitable manner.

Hereinafter, the terms “first” and “second” are only used for descriptive purposes, and are not to be construed as indicating or implying relative importance or implicitly indicating the number of indicated technical features. Thus, a feature defined with the term such as “first” or “second” may explicitly or implicitly include one or more of the features. In the description of the embodiments of the present disclosure, the term “a plurality of” or “the plurality of” means two or more unless otherwise specified.

In the description of some embodiments, the expressions “electrically connected” and “connected” and derivatives thereof may be used. For example, the term “electrically connected” may be used in the description of some embodiments to indicate that two or more components are in direct physical contact or electrical contact with each other. The embodiments disclosed herein are not necessarily limited to the content herein.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

In the description of the present disclosure, it will be understood that, orientations or positional relationships indicated by the terms such as “center”, “longitudinal”, “transverse”, “length”, “width”, “vertical”, “horizontal”, “inner”, and “outer” are based on orientations or positional relationships shown in the drawings, which is merely for convenience in description of the present disclosure and simplifying the description, but not to indicate or imply that the indicated apparatus or element must have a specific orientation, or be constructed and operated in a specific orientation.

It will be understood that, in a case that a layer or element is referred to be on another layer or substrate, it may be that the layer or element is directly on the another layer or substrate, or it may be that there is an intermediate layer between the layer or element and the another layer or substrate.

Exemplary embodiments are described herein with reference to sectional views and/or plan views as idealized exemplary drawings. In the drawings, thicknesses of layers and sizes of regions are enlarged for clarity. Thus, variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

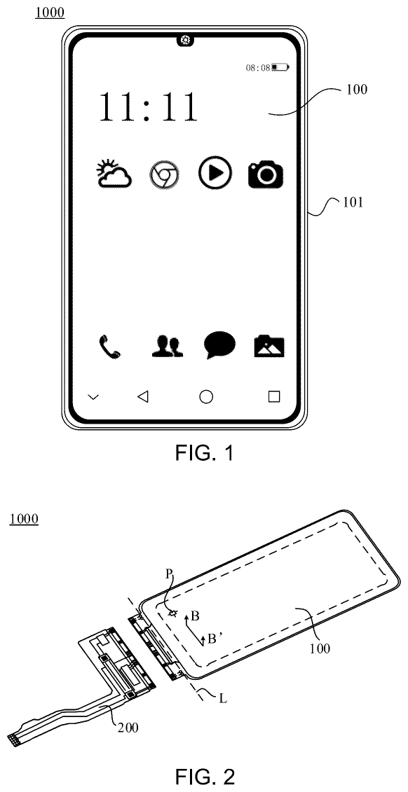

FIG. 1 is a top view of a display apparatus 1000, in accordance with some embodiments of the present disclosure. The display apparatus 1000 may be any device that can display images whether in motion (e.g., a video) or stationary (e.g., a still image), and regardless of text or image. More specifically, it is anticipated that the described embodiments may be implemented in or associated with a variety of electronic devices, such as (but not limited to), a mobile phone, a wireless device, a personal digital assistant (PDA), a virtual reality (VR) display, a hand-held or portable computer, a global positioning system (GPS) receiver/navigator, a camera, an moving picture experts group 4 (MP4) video player, a video camera, a game console, a watch, a clock, a calculator, a television monitor, a flat-panel display, a computer monitor, an automobile display (e.g., an odometer display), a navigator, a cockpit controller and/or display, a display of camera views (e.g., a display of a rear-view camera in a vehicle), an electronic photo, an electronic billboard or sign, a projector, a building structure, and a packaging and aesthetic structure (e.g., a display for displaying an image of a piece of jewelry).

As shown in FIGS. 1 and 2, the display apparatus 1000 includes a display panel 100.

The display panel 100 may be a liquid crystal display (LCD) panel; alternatively, the display panel 100 may be an electroluminescent display panel or a photoluminescent display panel. In a case where the display panel 100 is an electroluminescent display panel, the electroluminescent display panel may be an organic light-emitting diode (OLED) display panel or a quantum dot light-emitting diode (QLED) display panel. In a case where the display panel 100 is a photoluminescent display panel, the photoluminescent display panel may be a quantum dot photoluminescent display panel.

The display panel 100 includes a display side and a non-display side, the display side is a side where the display panel 100 emits light for display, and the non-display side is a side of the display panel 100 facing away from the display side.

In some embodiments, as shown in FIG. 2, the display apparatus 1000 further includes a flexible printed circuit 200.

The flexible printed circuit 200 is configured to be bonded to the display panel 100. Referring to FIG. 2, the flexible printed circuit 200 may be bent along the dotted line L toward the non-display side of the display panel 100, so that the flexible printed circuit 200 is located on a back side of the display panel 100.

In some embodiments, the display apparatus 1000 further includes a touch chip, a driver chip and other structures.

For example, the touch chip may be disposed on the flexible printed circuit 200. The touch chip is configured to be electrically connected to a touch structure in the display panel 100, so as to transmit touch signals to the touch structure to achieve the touch function.

For example, the driver chip may be disposed on the display panel 100. The driver chip is configured to be electrically connected to the signal lines in the display panel 100, so as to transmit light-emitting control signals to the sub-pixels electrically connected to the signal lines to achieve the luminous display function.

In some embodiments, as shown in FIG. 1, the display apparatus 1000 further includes a housing 101, and the housing is disposed at least partially around the display panel 100. For example, the housing may be a U-shaped groove, and the components such as display panel 100 and the bent flexible printed circuit 200 are disposed in the U-shaped groove.

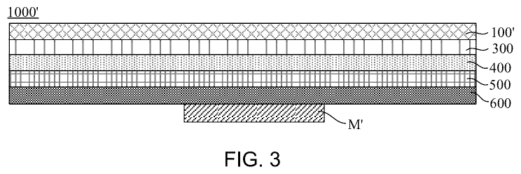

In the related art, as shown in FIG. 3, the display apparatus 1000′ further includes an optical fingerprint sensor M′.

Referring to FIG. 3, the optical fingerprint sensor M′ is provided under the screen, i.e., disposed on the non-display side of the display panel 100′. When a finger is placed on the display side of the display panel 100′ for fingerprint recognition, the light emitted by the display panel 100′ is irradiated on the finger, and the light is reflected by the fingerprint on the finger to form return light carrying fingerprint information; the return light passes through the display panel 100′ and finally reaches the optical fingerprint sensor M′ located on the non-display side of the display panel 100′ and is received by the optical fingerprint sensor M′, thereby achieving the fingerprint recognition and detection.

The inventors of the present disclosure found through research that the return light needs to pass through more film structures before reaching the optical fingerprint sensor M′.

For example, with the development of display technology, the display apparatus 1000′ having a flexible display panel 100′ has been rapidly developed. In the flexible display apparatus, a rigid support structure is provided on the non-display side of the display panel 100′ to support the display panel 100′ and other flexible components to avoid flexible deformation. The support layer is mostly made of stainless steel, has poor light transmittance and has a great impact on the transmission effect of the return light, which may easily cause the fingerprint recognition accuracy and recognition efficiency of the optical fingerprint sensor M′ to plummet.

Alternatively, for example, referring to FIG. 3, the non-display side of the display panel 100′ is provided with a back film 300, a buffer layer 400, an adhesive layer 500 a heat dissipation layer 600 and other film structures thereon, and these film structures lead to the low light transmission of the display apparatus, so that the intensity of the return light received by the optical fingerprint sensor M′ is reduced, and the functional implementation effect of the optical fingerprint sensor M′ is affected.

In order to solve the above problems, some embodiments of the present disclosure provide a display panel 100.

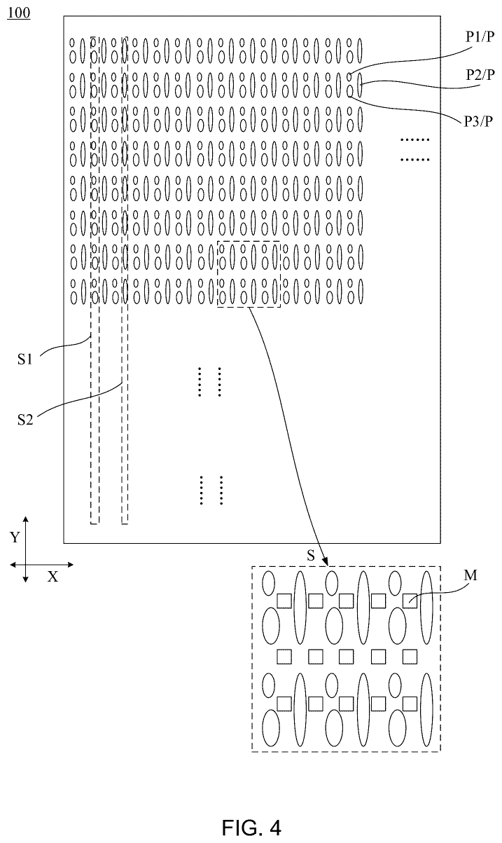

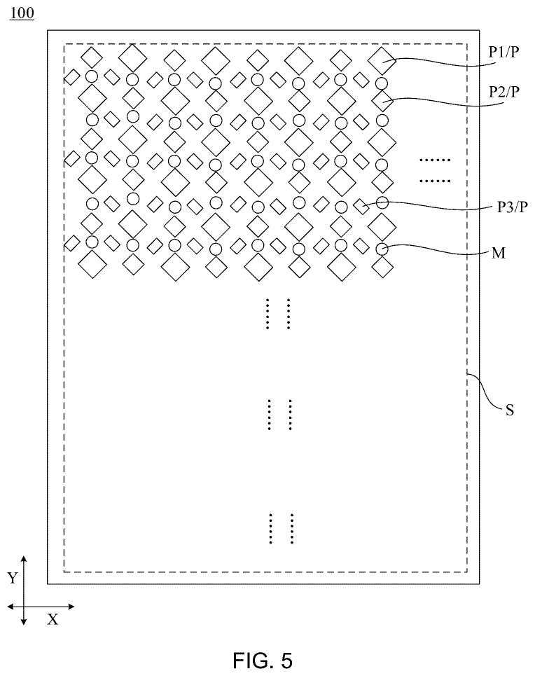

As shown in FIGS. 4 and 5, the display panel 100 includes a plurality of sub-pixels P.

For example, each sub-pixel P may emit one of blue light, green light, red light or white light.

For example, referring to FIGS. 4 and 5, the plurality of sub-pixels P include a first sub-pixel P1, a second sub-pixel P2 and a third sub-pixel P3, and the first sub-pixel P1, the second sub-pixel P2 and the third sub-pixel P3 respectively emit light of different colors. For example, the first sub-pixel P1 may emit red light, the second sub-pixel P2 may emit green light, and the third sub-pixel P3 may emit blue light.

For example, the plurality of sub-pixels P may be arranged in different manners.

For example, referring to FIG. 4, the plurality of sub-pixels P are arranged in a manner of “Real RGB”. The plurality of sub-pixels P are divided into a plurality of first pixel columns S1 and a plurality of second pixel columns S2, the first pixel columns S1 and the second pixel columns S2 each extend in a second direction Y, and the plurality of first pixel columns S1 and the plurality of second pixel columns S2 are arranged alternately in a first direction X.

The first pixel column S1 includes first sub-pixels P1 and third sub-pixels P3 that are arranged alternately in the second direction Y, and the second pixel column S2 includes second sub-pixels P2 arranged sequentially in the second direction Y.

For example, referring to FIG. 5, the plurality of sub-pixels P are arranged in a manner of “Diamond”. In the plurality of sub-pixels P, the first sub-pixels P1 and the second sub-pixels P2 are alternately arranged in the second direction Y, and the first sub-pixels P1 and the second sub-pixels P2 are also alternately arranged in the first direction X; the third sub-pixels P3 are arranged in the first direction X and the second direction Y in an array.

For example, in the plurality of sub-pixels P arranged in a manner of “Diamond”, the sub-pixel P is in a shape of a rectangle, and a diagonal line of the rectangle extends in the first direction X, and the other diagonal line of the rectangle extends in the second direction Y.

For example, in the plurality of sub-pixels P arranged in a manner of “Diamond”, the sub-pixel P is substantially in a shape of a rectangle, for example, the four corners of the rectangle are arc corners.

For example, in the plurality of sub-pixels P arranged in a manner of “Diamond”, at least one type of sub-pixels P is substantially fan-shaped.

For example, the plurality of sub-pixels P may be arranged in a manner of “GGRB”.

It will be noted that the arrangement of the plurality of sub-pixels P exemplified in the foregoing embodiments is illustrative, which does not limit the arrangement of the plurality of sub-pixels P in the display apparatus 1000 provided by the embodiments of the present disclosure.

The first direction X and the second direction Y intersect with each other. For example, referring to FIG. 4, the first direction X and the second direction Y are perpendicular to each other.

It will be noted that, the first direction X is a transverse direction of the display apparatus 1000, and the second direction Y is a longitudinal direction of the display apparatus 1000; alternatively, the first direction X is a row direction of an array arrangement of the plurality of sub-pixels P, and the second direction Y is a column direction of an array arrangement of the plurality of sub-pixels P.

The various accompanying drawings in the embodiments of the present disclosure are illustrated by taking an example in which the first direction X is the row direction and the second direction Y is the column direction. In the embodiments of the present disclosure, technical solutions obtained by rotating the drawings at a certain angle (e.g., 30 degrees, 45 degrees, or 90 degrees) shall also be included in the protection scope of the present disclosure.

As shown in FIGS. 4 and 5, the display panel 100 further includes at least one photosensor M, and each photosensor M is arranged adjacent to at least one sub-pixel P.

The photosensor M is configured to receive the return light formed after the light emitted by the sub-pixel P is reflected by the target object, so as to achieve the recognition, detection or scanning and imaging of the target object.

The “target object” may be a finger, a face, a picture, or other items that need to be identified, detected, or scanned by the photosensor M.

For example, in a case where the target object is a finger, the photosensor M is configured to receive the return light formed after the light emitted by the sub-pixel P is reflected by the finger, and analyze the return light, so as to achieve the fingerprint detection and the fingerprint recognition. For example, in a case where the target object is a face, the photosensor M is configured to receive the return light formed after the light emitted by the sub-pixel P is reflected by the face, and analyze the return light, so as to achieve the face detection and facial recognition. For example, in a case where the target object is a picture, the photosensor M is configured to receive the return light and form an image based on the return light, i.e., to achieve scanning and imaging of the picture.

It will be noted that the foregoing embodiments of the present disclosure only exemplarily illustrate the target object, and do not impose restrictions on the specific shape and type of the target object and the function of the photosensor M. For example, the photosensor M may also be configured to identify and detect palm prints, iris, and the like.

For example, referring to FIG. 4, the photosensors M are disposed in a functional device region S (a region where the photosensor(s) M are arranged in the display panel 100). The functional device region S only occupies a small part of the display panel 100, that is, the photosensors M are arranged locally. For example, the photosensors M are disposed only at a position of the display panel 100 that is convenient for pressing with the thumb. By arranging the photosensor M locally, it is possible to achieve corresponding functions (e.g., fingerprint recognition) and avoid the high cost problem caused by arranging the photosensors M on the full screen.

For example, referring to FIG. 5, the photosensors M are disposed in the functional device region S, and an area of the functional device region S is substantially equal to an area of the entire screen of the display panel 100; that is, the photosensors M are arranged on the full screen. By arranging the photosensors M on the entire screen of the display panel 100, it is possible to expand an effective region for recognition, detection, or scanning and imaging of the display panel 100, thereby expanding the usage scenarios of the display panel 100 provided with the photosensors M. For example, the display panel 100 provided with the photosensors M may be suitable for detecting, recognizing, or scanning large-sized target objects.

It will be noted that the setting position and area of the functional device region S, as well as the setting position, density, and number of the photosensors M are all set according to requirements. The foregoing embodiments only exemplarily illustrate the setting position of the photosensors M, and do not impose any restriction.

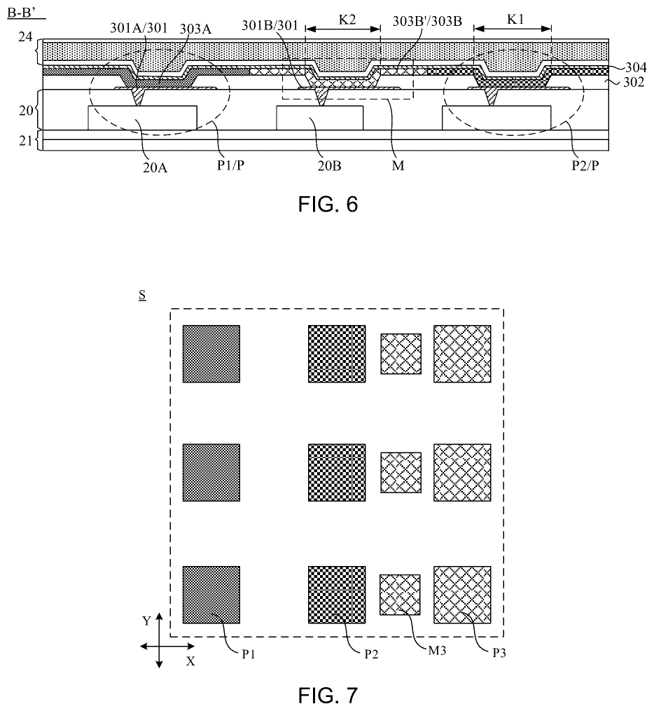

FIG. 6 is a sectional view of the display panel 100 taken along the section line B-B′ in FIG. 2. As shown in FIG. 6, the display panel 100 includes a substrate 21, a first electrode layer 301, a pixel definition layer 302, light-emitting patterns 303A, a light-absorbing pattern 303B and a second electrode layer 304.

The substrate 21 may be of a single-layer structure or a multi-layer structure. For example, the substrate 21 includes a flexible base layer and a buffer layer 102 that are stacked sequentially. For another example, the substrate 21 includes a plurality of flexible base layers and a plurality of buffer layers that are arranged alternately. A material of the flexible base layer may include polyimide, and a material of the buffer layer may include silicon nitride and/or silicon oxide, so as to achieve an effect of blocking moisture, oxygen and alkaline ions.

Referring to FIG. 6, the first electrode layer 301 is disposed on a side of the substrate 21. The first electrode layer 301 includes a first anode 301A and a second anode 301B, and the first anode 301A and the second anode 301B are configured to respectively transmit different anode signals.

For example, the first anode 301A and the second anode 301B are all configured to transmit a high-level voltage, for example, configured to transmit a power supply voltage.

For example, a material of the first anode 301A and a material of the second anode 301B each include indium tin oxide, indium zinc oxide, or zinc oxide.

Referring to FIG. 6, the pixel definition layer 302 is disposed on a side of the first electrode layer away from the substrate 21. The pixel definition layer 302 is provided with a first opening K1 and a second opening K2 therein. The first opening K1 corresponds in position to the first anode 301A, and the second opening K2 corresponds in position to the second anode 301B.

It will be noted that the description “the first opening K1 corresponds in position to the first anode 301A” means that an orthogonal projection of the first opening K1 on the substrate 21 is located within an orthographic projection of the first anode 301A on the substrate 21; similarly, the description “the second opening K2 corresponds in position to the second anode 301B” means that an orthogonal projection of the second opening K2 on the substrate 21 is located within an orthographic projection of the second anode 301B on the substrate 21. After the pixel definition layer 302 is disposed on a side of the first electrode layer 301, the first opening K1 may expose the first anode 301A, and the second opening K2 may expose the second anode 301B.

Each first opening K1 is used to define an effective light-emitting region of a sub-pixel P. Each second opening K2 is used to define an effective light-absorbing region of a photosensor M.

For example, a section of the first opening K1 parallel to the substrate 21 may be in a shape of a rectangle, circle or ellipse, and a section of the second opening K2 parallel to the substrate 21 may also be in a shape of a rectangle, circle or ellipse.

Referring to FIG. 6, at least portion of the light-emitting pattern 303A is disposed in the first opening K1.

For example, the portion of the light-emitting pattern 303A disposed in the first opening K1 is in electrical contact with the first anode 301A.

For example, the light-emitting pattern 303A may be formed in the first opening K1 by evaporation.

A material of the light-emitting pattern 303A may be fluorescent luminescent material or a phosphorescent luminescent material, which is capable of emitting red light, green light, blue light or white light.

For example, the light-emitting patterns 303A may be formed by evaporation sequentially according to the different colors that capable of emitting. For example, all the light-emitting patterns 303A capable of emitting green light are formed by evaporation first, and then all the light-emitting patterns 303A capable of emitting blue light are formed by evaporation, and then all the light-emitting patterns 303A capable of emitting red light are formed by evaporation.

Referring to FIG. 6, at least portion of the light-absorbing pattern 303B is disposed in the second opening K2.

For example, the portion of the light-absorbing pattern 303B located in the second opening K2 is in electrical contact with the second anode 301B.

For example, the light-absorbing pattern 303B may be formed in the second opening K2 by evaporation.

For example, after all the light-emitting patterns 303A capable of emitting red light, blue light and green light are all formed by evaporation, the light-absorbing pattern 303B may be formed in the second opening K2.

For example, the light-absorbing pattern 303B is capable of absorbing the light emitted by the light-emitting pattern 303A. For example, the light-absorbing pattern 303B is capable of absorbing the light directly emitted by the light-emitting pattern 303A, and the light that is emitted by the light-emitting pattern 303A and then reflected by the target object or other structures.

Referring to FIG. 6, the second electrode layer 304 is disposed on a side of the pixel definition layer 302 away from the substrate 21 and covers the light-emitting pattern 303A and the light-absorbing pattern 303B.

For example, a material of the second electrode layer 304 may include lithium (Li), aluminum (Al), magnesium (Mg), or silver (Ag).

For example, the second electrode layer 304 is configured to transmit a low-level voltage.

Referring to FIG. 6, the sub-pixel P includes the first anode 301A, the light-emitting pattern 303A, and a portion of the second electrode layer 304 covering the light-emitting pattern 303A.

An electric field is developed due to the combined action of the high-level voltage transmitted by the first anode 301A and the low-level voltage transmitted by the portion of the second electrode layer 304 covering the light-emitting pattern 303A. Under the driving of the electric field, the holes in the first anode 301A and the electrons in the second electrode layer 304 are all transmitted to the light-emitting pattern 303A located in the first opening K1, and the holes and electrons combine in the light-emitting pattern 303A to form excitons to emit light.

The light emitted by the light-emitting pattern 303A is emitted through the first opening K1, that is, a region where the first opening K1 is located is an effective light-emitting region of the sub-pixel P.

Referring to FIG. 6, the photosensor M includes a second anode 301B, a light-absorbing pattern 303B, and a portion of the second electrode layer 304 covering the light-absorbing pattern 303B.

The light-absorbing pattern 303B generates photo-induced carriers after absorbing light (e.g., light emitted by the sub-pixel P and then reflected by the target object). An electric field is developed due to the combined action of the high-level voltage transmitted by the second anode 301B and the low-level voltage transmitted by the portion of the second electrode layer 304 covering the light-absorbing pattern 303B. Due to the action of the electric field, it is possible to achieve the transmission and analysis of the photo-induced carriers, so as to achieve optical detection, optical recognition, and scanning and imaging.

After being emitted by the light-emitting pattern 303A is irradiated onto the target object and is reflected by the target object, the light is incident on the light-absorbing pattern 303B through the second opening K2. That is, a region where the second opening K2 is located is an effective light-absorbing region of the photosensor M.

The photosensor M is provided, and the light-absorbing pattern 303B of the photosensor M is arranged between the first electrode layer 301 and the second electrode layer 304, that is, the photosensor M is arranged in the screen of the display panel 100. Thus, compared with arranging the photosensor M under the screen, arranging the photosensor M in the screen may effectively shorten a vertical distance between the photosensor M and the target object, thereby reducing the loss of the return light during the transmission process, and improving the function realization effect of the photosensor M, for example, improving the accuracy and sensitivity of fingerprint recognition; furthermore, the photosensor M is effectively applied to the display apparatus 1000, so that the display apparatus 1000 may achieve multiple functions such as recognition, detection, and scanning and imaging of the target object; moreover, compared with the traditional optical fingerprint sensors, the photosensor M has the advantages of rapid response, high sensitivity and long service life.

In some embodiments, as shown in FIGS. 4 and 5, the display panel 100 includes a plurality of sub-pixels P and at least one photosensor M. The at least one photosensor M may absorb at least one of red light, blue light or green light.

For example, the at least one photosensor M may absorb only one color, thereby achieving the recognition and detection of the target object such as fingerprint, and achieving functions such as scanning and imaging of a single color.

For example, referring to FIG. 7, in the plurality of photosensors M in the functional device region S, each photosensor M (i.e., a third photosensor M3) absorbs only blue light, thereby achieving the recognition and detection of the target object, or achieving the scanning and imaging of the blue color, i.e., the image obtained by scanning and imaging is blue.

For example, the at least one photosensor M may absorb light of two colors, thereby achieving the recognition and detection of the target object such as fingerprint, and achieving the functions such as scanning and imaging of the specific color (e.g., blue-green).

For example, referring to FIG. 8, in the plurality of photosensors M in the functional device region S, some photosensors M (i.e., first photosensors M1) absorb only red light, and some other photosensors M (i.e., second photosensors M2) absorb only green light. Thus, the plurality of photosensors M in the functional device region S absorb light of two colors of red light and green light, thereby achieving the recognition and detection of the target object, or achieving the scanning and imaging of yellow (a mixture of red and green), i.e., the image obtained by scanning and imaging is yellow.

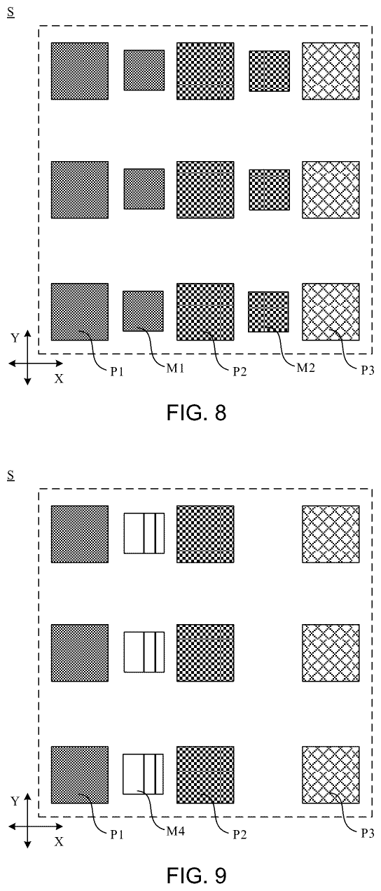

Alternatively, referring to FIG. 9, in the plurality of photosensors M in the functional device region S, each photosensor M (i.e., fourth photosensor M4 in FIG. 9) may absorb both red light and green light, thereby achieving the recognition and detection of the target object, or achieving the scanning and imaging of yellow (a mixture of red and green), i.e., the image obtained by scanning and imaging is yellow.

For example, the at least one photosensor M may absorb three colors, thereby achieving the recognition and detection of the target object such as fingerprint, and achieving functions such as scanning and imaging of full-color.

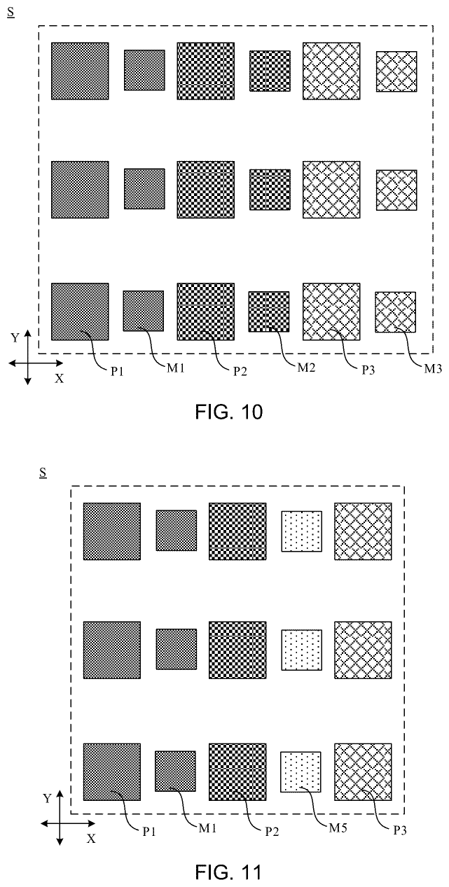

For example, referring to FIG. 10, in the plurality of photosensors M in the functional device region S, some photosensors M (i.e., first photosensors M1) absorb only red light, and some photosensors M (i.e., second photosensors M2) may absorb only green light, and some other photosensors M (i.e., third photosensors M3) may absorb only blue light. Thus, the plurality of photosensors M in the functional device region S absorb light of three colors of red light, green light and blue color, thereby achieving the recognition and detection of the target object, or achieving scanning and imaging of full-color, i.e., the image obtained by scanning and imaging displays all the colors of the scanned picture, so that the realism of scanning and imaging is high.

Alternatively, for example, referring to FIG. 11, in the plurality of photosensors M in the functional device region S, some photosensors M (i.e., fifth photosensors M5 in FIG. 11) may absorb both blue light and green light, and some other photosensors M (i.e., first photosensors M1) absorb only red light. Thus, the plurality of photosensors M in the functional device region S may absorb light of three colors of red light, green light and blue light, thereby achieving the recognition and detection of the target object, or achieving scanning and imaging of full-color.

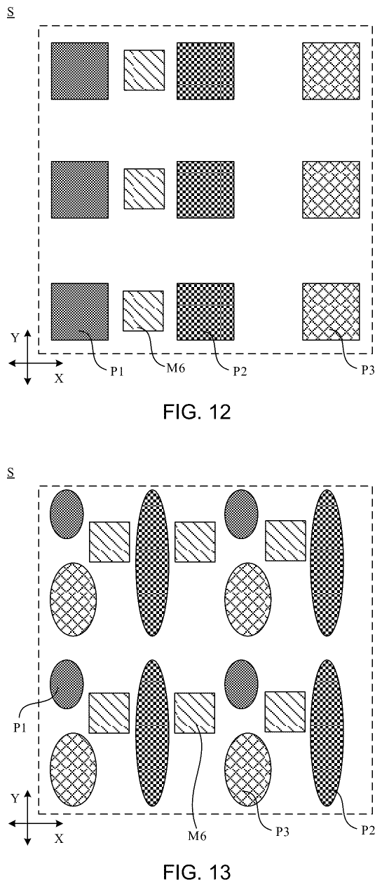

Alternatively, referring to FIG. 12, in the plurality of photosensors M in the functional device region S, each photosensor M (i.e., sixth photosensor M6 in FIG. 12) may absorb all of red light, green light and blue light, thereby achieving the recognition and detection of the target object, or achieving scanning and imaging of full-color.

According to the foregoing description, in the display apparatus 1000 provided by the embodiments of the present disclosure, the photosensor(s) M may perform scanning and imaging of full-color, and in a case where the light-absorbing pattern 303B of a photosensor M can absorb light of three colors, in the process of scanning and imaging, the red, blue and green colors of the target object may be captured simultaneously, thereby avoiding the need to sequentially capture different colors in a time-divided manner and then synthesize an colorful image, and greatly improving the efficiency of scanning and imaging.

In some embodiments, as shown in FIG. 7, in a case where the light-absorbing pattern 303B of a photosensor M can absorb the light of one color, the photosensor M capable of absorbing the light of target color and the sub-pixel P capable of emitting the light of target color are arranged adjacent to each other.

It will be noted that the light of target color may be one of red light, blue light and green light.

For example, a photosensor M capable of absorbing red light is arranged adjacent to a sub-pixel P capable of emitting red light, a photosensor M capable of absorbing green light is arranged adjacent to a sub-pixel P capable of emitting green light, and a photosensor M capable of absorbing blue light is arranged adjacent to a sub-pixel P capable of emitting blue light.

For example, referring to FIG. 10, the plurality of sub-pixels P includes a first sub-pixel P1, a second sub-pixel P2 and a third sub-pixel P3, and the first sub-pixel P1 emits red light, the second sub-pixel P2 emits green light, and the third sub-pixel P3 emits blue light. The plurality of photosensors M includes a first photosensor M1, a second photosensor M2, and a third photosensor M3. The first photosensor M1 may absorb red light, the second photosensor M2 may absorb green light, and the third photosensor M3 may absorb blue light.

The first photosensor M1 is arranged adjacent to the first sub-pixel P1, the second photosensor M2 is arranged adjacent to the second sub-pixel P2, and the third photosensor M3 is arranged adjacent to the third sub-pixel P3.

The photosensor M capable of absorbing light of a target color is arranged adjacent to the sub-pixel P capable of emitting light of the target color, which may improve the absorption efficiency of the photosensor M for the light of target color and avoid interference from light except for the light of target color on the photosensor M, so that the function realization effect of the photosensor M is improved, for example, the speed and accuracy of fingerprint recognition are improved.

In some embodiments, as shown in FIG. 9, in the case where the light-absorbing pattern 303B of the photosensor M is capable of absorbing light of two colors, the photosensor M capable of absorbing both light of a first target color and light of a second target color is arranged between the sub-pixel P capable of emitting the light of the first target color and the sub-pixel P capable of emitting the light of the second target color.

It will be noted that the light of the first target color may be one of red light, blue light and green light, and the light of the second target color may be another one of red light, blue light and green light.

For example, referring to FIG. 9, the photosensor M may absorb both red light and green light, and the photosensor M is arranged between the first sub-pixel P1 (capable of emitting red light) and the second sub-pixel P2 (capable of emit green light).

With the above arrangement, it is possible to improve the absorption efficiency of the photosensor M for the light of the first target color and the light of the second target color, which may avoid interference from light except for the light of the first target color and the light of the second target color on the photosensor M, so that the function realization effect of the photosensor M is improved, for example, the speed and accuracy of fingerprint recognition are improved.

In some embodiments, referring to FIG. 12, the light-absorbing pattern 303B of the photosensor M is capable of absorbing light of three colors, and the light of three colors include red light, blue light and green light. The photosensor M capable of absorbing light of three colors is arranged adjacent to any sub-pixel P.

For example, referring to FIG. 12, the light-absorbing pattern 303B of the photosensor M is capable of absorbing light of three colors, and the light of three colors includes red light, blue light and green light. The photosensor M capable of absorbing light of three colors is arranged adjacent to the sub-pixel P capable of emitting green light (i.e., the second sub-pixel P2).

For example, the photosensor M may absorb all of red light, green light and blue light; referring to FIG. 12, the photosensor M is arranged between the first sub-pixel P1 (capable of emitting red light) and the second sub-pixel P2 (capable of emitting green light); alternatively, the photosensor M is arranged between the third sub-pixel P3 (capable of emitting blue light) and the second sub-pixel P2 (capable of emitting green light).

With the above arrangement, while scanning and imaging of full-color is achieved, the absorption efficiency of the photosensor M for green light may be improved, and the function implementation effect of the photosensor M may be optimized, for example, the color accuracy of the image after scanning and imaging are performed by the photosensor M may be improved.

In some embodiments, in a case where the plurality of sub-pixels P are arranged in different manners, the photosensors M are arranged at different locations.

For example, referring to FIG. 13, the plurality of sub-pixels P are arranged in a manner of “Real RGB”, and the photosensor M may be arranged between the first sub-pixel P1, second sub-pixel P2 and third sub-pixel P3 that are adjacent to one another.

In a case where the photosensor M (i.e., sixth photosensor M6) may absorb all of red light, blue light and green light, the photosensor M is arranged between the first sub-pixel P1, second sub-pixel P2 and third sub-pixel P3 that are adjacent to one another. Thus, it is possible to ensure that the photosensor M evenly absorbs red light, blue light and green light, and avoid the problem of color shift caused by a case that the photosensor M insufficiently absorbs one of red light, blue light and green light, thereby facilitating the imaging of full-color for the photosensor M during the scanning and imaging process, and improving the color accuracy of the image after scanning and imaging are performed.

In some embodiments, the photosensors M may be arranged around the sub-pixel P. For example, four photosensors M are arranged around one sub-pixel P, and the four photosensors M are distributed in an array in the first direction and the second direction. For example, if the photosensor M needs to absorb red light, multiple photosensors M are arranged around the sub-pixel P capable of emitting red light, thereby increasing the intensity of red light that the photosensor M can absorb.

With the development of display technology, various functions of the display apparatus 1000 are increasingly required. For example, the response speed and accuracy of the fingerprint recognition of the display apparatus 1000 are increasingly required. Therefore, various performances of the photosensor M provided in the foregoing embodiments are subject to severe challenges.

In order to improve various performances of the photosensor M, in some embodiments of the present disclosure, the structure of the aforementioned display panel 100 is designed as follows.

In some embodiments, as shown in FIG. 6, the light-absorbing pattern 303B includes a light-absorbing sub-pattern 303B′, and the light-absorbing sub-pattern 303B′ is capable of absorbing light of at least one color.

For example, the light-absorbing sub-pattern 303B′ may absorb one of red light, blue light and green light, e.g., absorb only green light, so that the photosensor M absorbs light of only one color.

In a case where the light-absorbing pattern 303B absorbs light of only one color, the photosensor M is configured to achieve the recognition function of fingerprint, palmprint, iris or face, or to achieve the scanning and imaging function of a single color.

For example, the light-absorbing sub-pattern 303B′ may absorb two of red light, blue light and green light, e.g., absorb both red light and blue light, so that one photosensor M absorbs light of two colors.

In a case where the light-absorbing pattern 303B absorbs light of two colors, the photosensor M is configured to achieve the recognition function of fingerprint, palmprint, iris or face, or to achieve the scanning and imaging function of a specific color.

For example, the light-absorbing sub-pattern 303B′ may absorb all of red light, blue light and green light, so that the photosensor M may absorb light of three colors.

In a case where the light-absorbing pattern 303B absorbs all of red color, blue light and green light, the photosensor M is configured to achieve the recognition function of fingerprint, palmprint, iris or face, or to achieve the scanning and imaging function of full-color.

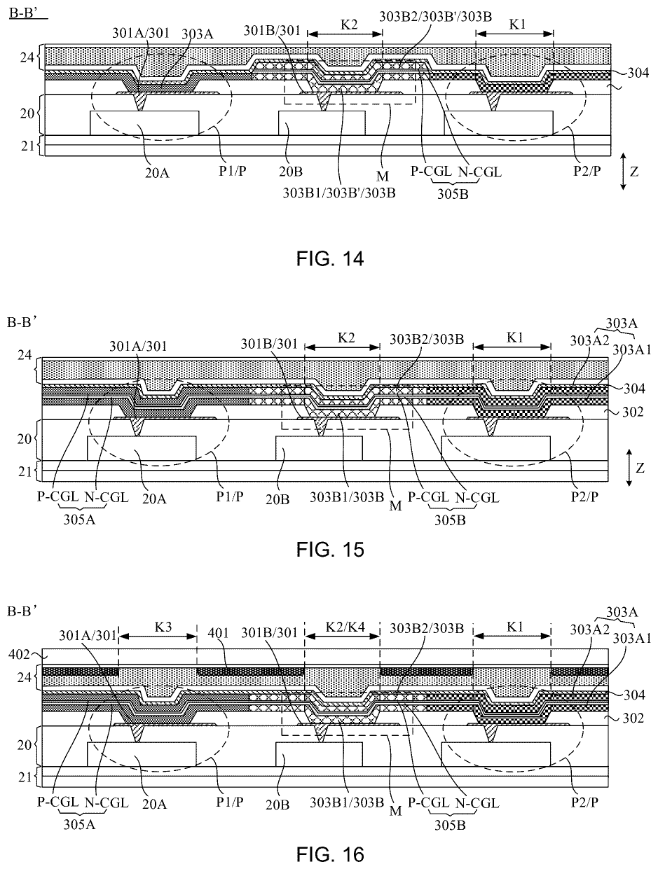

In some embodiments, as shown in FIG. 14, the light-absorbing pattern 303B includes a plurality of light-absorbing sub-pattern 303B′ that are sequentially arranged in a direction Z perpendicular to the substrate 21, and each light-absorbing sub-pattern 303B′ is capable of absorbing light of at least one color.

For example, in the direction perpendicular to the substrate 21, the light-absorbing sub-patterns 303B′ that are arranged adjacent to each other are in direct or indirect electrical contact to achieve the series connection between the plurality of light-absorbing sub-patterns 303B′, thereby ensuring that the photosensor M is in an on state.

By arranging the plurality of layers of light-absorbing sub-patterns 303B′, the light absorption intensity of the photosensor M for the return light is greatly improved under driving by a relatively small current. Thus, the function realization effect of the photosensor M may be improved, and moreover, the driving current in the photosensor M is relatively small, which may prolong the service life.

In some embodiments, as shown in FIG. 14, the light-absorbing pattern 303B includes two light-absorbing sub-patterns 303B′ that are arranged in sequence in the direction perpendicular to the substrate 21. Referring to FIG. 14, the light-absorbing pattern 303B includes a first light-absorbing sub-pattern 303B1 and a second light-absorbing sub-pattern 303B2.

For example, the light-absorbing pattern 303B may absorb one of red light, blue light and green light.

In this case, the color of the light that the first light-absorbing sub-pattern 303B1 is capable of absorbing is the same as the color of the light that the second light-absorbing sub-pattern 303B2 is capable of absorbing. For example, both the first light-absorbing sub-pattern 303B1 and the second light-absorbing sub-pattern 303B2 absorb only blue light, or both absorb only green light.

For example, the light-absorbing pattern 303B may absorb two of red light, blue light and green light.

For example, in the case where the light-absorbing pattern 303B absorbs two of red light, blue light and green light, the color of the light that the first light-absorbing sub-pattern 303B1 is capable of absorbing is the same as the color of the light that the second light-absorbing sub-pattern 303B2 is capable of absorbing.

For example, the light-absorbing pattern 303B may absorb both green light and red light; the first light-absorbing sub-pattern 303B1 may absorb both green light and red light, and the second light-absorbing sub-pattern 303B2 may also absorb both green light and red light.

Alternatively, for example, in the case where the light-absorbing pattern 303B absorbs two of red light, blue light and green light, the color of the light that the first light-absorbing sub-pattern 303B1 is capable of absorbing is not exactly the same as the color of the light that the second light-absorbing sub-pattern 303B2 is capable of absorbing.

For example, the first light-absorbing sub-pattern 303B1 is capable of absorbing green light, and the second light-absorbing sub-pattern 303B2 is capable of absorbing red light. Alternatively, for example, the first light-absorbing sub-pattern 303B1 is capable of absorbing green light, and the second light-absorbing sub-pattern 303B2 is capable of absorbing red light.

For example, the light-absorbing pattern 303B may absorb red light, blue light and green light.

For example, in the case where the light-absorbing pattern 303B absorbs red light, blue light and green light, the color of the light that the first light-absorbing sub-pattern 303B1 is capable of absorbing is the same as the color of the light that the second light-absorbing sub-pattern 303B2 is capable of absorbing.

For example, both the first light-absorbing sub-pattern 303B1 and the second light-absorbing sub-pattern 303B2 absorb red light, blue light and green light.

Alternatively, for example, in the case where the light-absorbing pattern 303B absorbs red light, blue light and green light, the color(s) of the light that the first light-absorbing sub-pattern 303B1 is capable of absorbing are not exactly the same as the color(s) of the light that the second light-absorbing sub-pattern 303B2 is capable of absorbing.

For example, one of the first light-absorbing sub-pattern 303B1 and the second light-absorbing sub-pattern 303B2 is capable of absorbing red light and blue light, and the other of the first light-absorbing sub-pattern 303B1 and the second light-absorbing sub-pattern 303B2 is capable of absorbing green light.

For example, one of the first light-absorbing sub-pattern 303B1 and the second light-absorbing sub-pattern 303B2 is capable of absorbing red light and green light, and the other of the first light-absorbing sub-pattern 303B1 and the second light-absorbing sub-pattern 303B2 is capable of absorbing blue light.

For example, one of the first light-absorbing sub-pattern 303B1 and the second light-absorbing sub-pattern 303B2 is capable of absorbing blue light and blue light, and the other of the first light-absorbing sub-pattern 303B1 and the second light-absorbing sub-pattern 303B2 is capable of absorbing red light.

For example, one of the first light-absorbing sub-pattern 303B1 and the second light-absorbing sub-pattern 303B2 is capable of absorbing green light and red light, and the other of the first light-absorbing sub-pattern 303B1 and the second light-absorbing sub-pattern 303B2 is capable of absorbing green light and blue light.

For example, one of the first light-absorbing sub-pattern 303B1 and the second light-absorbing sub-pattern 303B2 is capable of absorbing green light, and the other of the first light-absorbing sub-pattern 303B1 and the second light-absorbing sub-pattern 303B2 is capable of absorbing red light, blue light and green light.

For example, one of the first light-absorbing sub-pattern 303B1 and the second light-absorbing sub-pattern 303B2 is capable of absorbing green light and blue light, and the other of the first light-absorbing sub-pattern 303B1 and the second light-absorbing sub-pattern 303B2 is capable of absorbing red light, blue light, and green light.

It will be noted that the first light-absorbing sub-pattern 303B1 and second light-absorbing sub-pattern 303B2 may be replaced with each other. For example, relative to the first light-absorbing sub-pattern 303B1, the second light-absorbing sub-pattern 303B2 may be disposed closer to the substrate 21 or may be disposed further away from the substrate 21.

For example, the light that the first light-absorbing sub-pattern 303B1 is capable of absorbing and the light that the second light-absorbing sub-pattern 303B2 is capable of absorbing are complementary to each other; that is, the light that the first light-absorbing sub-pattern 303B1 is capable of absorbing and the light that the second light-absorbing sub-pattern 303B2 is capable of absorbing are mixed into white light. For example, the light that the first light-absorbing sub-pattern 303B1 is capable of absorbing is blue-green light, and the light that the second light-absorbing sub-pattern is capable of absorbing is red light.

By setting the light that the first light-absorbing sub-pattern 303B1 is capable of absorbing and the light that the second light-absorbing sub-pattern 303B2 is capable of absorbing are complementary to each other, the light-absorbing pattern 303B formed by the first light-absorbing sub-pattern 303B1 and the second light-absorbing sub-pattern 303B2 may achieve scanning and imaging of full-color.

In some embodiments, a wavelength of the light that the first light-absorbing sub-pattern 303B1 is capable of absorbing and a wavelength of the light that the second light-absorbing sub-pattern 303B2 is capable of absorbing are substantially in a same range. Thus, the light that the first light-absorbing sub-pattern 303B1 is capable of absorbing and the light that the second light-absorbing sub-pattern 303B2 is capable of absorbing have substantially the same color.

For example, the wavelength of the light that the first light-absorbing sub-pattern 303B1 is capable of absorbing and the wavelength of the light that the second light-absorbing sub-pattern 303B2 is capable of absorbing are both in a range of approximately 510 nm to approximately 560 nm, such as 530 nm. That is, the light that the first light-absorbing sub-pattern 303B1 is capable of absorbing and the light that the second light-absorbing sub-pattern 303B2 is capable of absorbing are both green light.

For example, the wavelength of the light that the first light-absorbing sub-pattern 303B1 is capable of absorbing and the wavelength of the light that the second light-absorbing sub-pattern 303B2 is capable of absorbing are both in a range of approximately 430 nm to approximately 560 nm, such as 530 nm. That is, both the first light-absorbing sub-pattern 303B1 and the second light-absorbing sub-pattern 303B2 are capable of absorbing blue light and green light.

For example, the wavelength of the light that the first light-absorbing sub-pattern 303B1 is capable of absorbing and the wavelength of the light that the second light-absorbing sub-pattern 303B2 is capable of absorbing are both in a range of approximately 393 nm to approximately 763 nm. That is, both the first light-absorbing sub-pattern 303B1 and the second light-absorbing sub-pattern 303B2 are capable of absorbing red light, blue light and green light.

In some embodiments, the wavelength of the light that the first light-absorbing sub-pattern 303B1 is capable of absorbing is in a range that is not exactly the same as the wavelength of the light that the second light-absorbing sub-pattern 303B2 is capable of absorbing. Therefore, the colors of light that the first light-absorbing sub-pattern 303B1 and the second light-absorbing sub-pattern 303B2 are capable of absorbing are not exactly the same.

For example, the wavelength of the light that the first light-absorbing sub-pattern 303B1 is capable of absorbing is in a range of approximately 430 nm to approximately 560 nm, and the wavelength of the light that the second light-absorbing sub-pattern 303B2 is capable of absorbing is in a range of approximately 510 nm to approximately 660 nm. That is, the light that the first light-absorbing sub-pattern 303B1 is capable of absorbing is blue light and green light, and the light that the second light-absorbing sub-pattern 303B2 is capable of absorbing is red light and green light.

In some embodiments, the light-absorbing patterns 303B capable of absorbing light of different colors correspond to materials with different band gaps.

For example, the light-absorbing pattern 303B that capable of absorbing red light corresponds to a band gap of 1.92, the light-absorbing pattern 303B that capable of absorbing blue light corresponds to a band gap of 2.61, and the light-absorbing pattern 303B that capable of absorbing green light corresponds to a band gap of 2.3. By adjusting the band gap of the light-absorbing pattern 303B, it is possible to control the wavelength of the light that the light-absorbing pattern 303B is capable of absorbing, thereby obtaining the light-absorbing patterns 303B that capable of absorbing light of different colors.

In addition, by reducing the band gap of the light-absorbing pattern 303B (e.g., the light that the light-absorbing pattern 303B is capable of absorbing is green light, by reducing the band gap of the light-absorbing pattern 303B in the process of absorbing green light), it is possible to reduce the absorption for the stray light except for green light and improve the purity and efficiency of absorbing green light.

For example, in the case where the light-absorbing pattern 303B includes a plurality of light-absorbing sub-patterns 303B′, band gaps of different light-absorbing sub-patterns 303B′ may be the same. For example, in a case where the plurality of light-absorbing sub-patterns 303B′ each absorb light of only one color, the band gaps of the plurality of light-absorbing sub-patterns 303B′ are the same, thereby improving the purity of absorbing the light and avoiding the interference of stray light.

For example, in the case where the light-absorbing pattern 303B includes a plurality of light-absorbing sub-patterns 303B′, the band gaps of different light-absorbing sub-patterns 303B′ may not be exactly the same. For example, in the case where the light-absorbing pattern 303B is capable of absorbing red light and green light, one of the plurality of light-absorbing sub-patterns 303B′ may have a wide band gap and may absorb both red light and green light, and the other one of the plurality of light-absorbing sub-patterns 303B′ may have a narrow band gap and may absorb only green light. Thus, in a case where the light-absorbing pattern 303B is capable of absorbing red light and green light, the absorption rate of green light is improved, thereby achieving adjustment of the color of the light that is capable of absorbing in a small range.

In some embodiments, a material of the light-absorbing pattern 303B includes a perovskite-based semiconductor material. For example, the light-absorbing pattern 303B is a halide perovskite material. For example, the material of the light-absorbing pattern 303B includes organic-inorganic hybrid perovskite and all-inorganic perovskite.

The perovskite material has the characteristic of adjustable band gap, and the wavelength of the light that the light-absorbing pattern 303B is capable of absorbing may be controlled by adjusting the band gap of the perovskite material, so that the light-absorbing patterns 303B are capable of absorbing light of different colors.

In some embodiments, the molecular formula of the material of the light-absorbing pattern 303B is RNH₃BY₃₋ₘXₘ.

R is CₙH₂ₙ₊₁, for example, may be CH₃. B is a metal element, for example, may be a metal element such as Pb or Sn. X and Y are different halogen elements, such as Cl, Br, or I. m and n are both an integer.

For example, the molecular formula of the material of the light-absorbing pattern 303B may be C₃H₇NH₃SnICl₂, C₄H₉NH₃PbBrCl₂, C₅H₁₁NH₃SnI₂Cl, C₃H₇NH₃SnCl₃ or C₆H₁₃NH₃PbIBr₂.

For example, the material of the light-absorbing pattern 303B may be synthesized in one step by dual-source co-evaporation, and the equation is as follows:

RNH₃X+BY→RNH₃BY₃₋ₘXₘ

The evaporation temperature of RNH₃X is approximately 120° C., and the melting point temperature of BY is approximately 420° C. There is no by-product by co-evaporation, and only RNH₃BY₃₋ₘXₘ is produced.

The materials corresponding to the light-absorbing patterns 303B that capable of absorbing light of different colors have different mass ratios of X and Y.

For example, by controlling the mass ratio of X and Y, the band gap of the light-absorbing pattern 303B may be adjusted from 1.15 eV to 3.1 eV, and the maximum absorption wavelength of the light-absorbing 303B is in a range of 393 nm to 763 nm. That is, it may be possible to satisfy the need that the light-absorbing pattern 303B is able to absorb red light, blue light, and green light individually or simultaneously, which is beneficial to realizing scanning and imaging of full-color of the photosensor M.

For example, the band gap may be adjusted by controlling the bond length and bond angle of the perovskite material, or adjusting the chemical bonds, or adjusting the proportion of atoms in the perovskite.

For example, other organic cations may be used to replace the cation RNH₃⁺, thereby changing the bond length and bond angle in the perovskite molecular structure to change the band gap. Alternatively, by adjusting the chemical bond, for example, replacing part of Pb²⁺ in CH₃NH₃PbI₃ with Sn²⁺, the band gap is reduced from 1.55 to 1.17. Alternatively, the band gap may be adjusted by changing the proportion of atoms in RNH₃BY₃₋ₘXₘ.

It will be noted that in the above embodiments of the present disclosure, the material of the light-absorbing pattern 303B is only exemplarily illustrated and the specific material composition is not limited; any material that capable of achieving the effect (including wavelength, band gap, color of the light that capable of absorbing and the like) of the light-absorbing pattern 303B described in any of the aforementioned embodiments is within the scope of protection of the present disclosure.

In some embodiments, as shown in FIG. 14, the display panel 100 further includes a second heterojunction 305B.

The second heterojunction 305B is disposed between two adjacent light-absorbing sub-patterns 303B′, and the second heterojunction 305B is configured to improve the conduction efficiency of carriers between the two adjacent light-absorbing sub-patterns 303B′ to enhance the light absorption intensity and response speed of the photosensor M.

For example, in a case where the light-absorbing pattern 303B includes a plurality of light-absorbing sub-patterns 303B′, every two adjacent light-absorbing sub-patterns 303B′ are provided a second heterojunction 305B therebetween.

For example, as shown in FIG. 14, in the case where the light-absorbing pattern 303B includes a first light-absorbing sub-pattern 303B1 and a second light-absorbing sub-pattern 303B2, the second heterojunction 305B is disposed between the first light-absorbing sub-pattern 303B1 and the second light-absorbing sub-pattern 303B2.

In some embodiments, as shown in FIG. 15, the light-emitting pattern 303A includes a first light-emitting sub-pattern 303A1 and a second light-emitting sub-pattern 303A2 that are sequentially arranged in the direction Z perpendicular to the substrate 21.

For example, the first light-emitting sub-pattern 303A1 is in direct or indirect electrical contact with the second light-emitting sub-pattern 303A2, that is, the first light-emitting sub-pattern 303A1 and the second light-emitting sub-pattern 303A2 are connected in series.

By providing the first light-emitting sub-pattern 303A1 and the second light-emitting sub-pattern 303A2 that are connected in series, the light-emitting current of the sub-pixel P may be greatly reduced under the same light-emitting intensity, which improves the service life of the sub-pixel P, and facilitates the development and mass production of new technologies with high service life such as vehicle equipment.

For example, referring to FIG. 15, the display panel 100 further includes a first heterojunction 305A disposed between the first light-emitting sub-pattern 303A1 and the second light-emitting sub-pattern 303A2.

The first heterojunction 305A is configured to improve the conduction efficiency of carriers between the first light-emitting sub-pattern 303A1 and the second light-emitting sub-pattern 303A2, thereby optimizing the display effect of the display panel 100.

For example, referring to FIG. 15, in a case where the display panel 100 includes both the first heterojunction 305A and the second heterojunction 305B, the first heterojunction 305A and the second heterojunction 305B are connected to be a one-piece structure. For example, the first heterojunction 305A and the second heterojunction 305B are in a one-piece structure.

For example, the heterojunctions (including the first heterojunction 305A and the second heterojunction 305B) include at least two layers of semiconductor films. For example, referring to FIGS. 14 and 15, the heterojunction includes a first semiconductor film P-CGL and a second semiconductor film N-CGL.

For example, the material of the first semiconductor film P-CGL and the second semiconductor film N-CGL may be a compound such as gallium arsenide or a semiconductor alloy such as silicon-germanium.

By providing the first heterojunction 305A and the second heterojunction 305B, the conduction efficiency of carriers in the photosensor M is improved, which enhances the sensing sensitivity of the photosensor M, so that both the light-absorbing effect of the photosensor M in the display panel 100 and the light-emitting effect of the sub-pixel P have been optimized.

In the light-absorbing process of the photosensor M, the absorption amount of stray light will affect the absorption effective of the effective return light. The stray light refers to light except for the return light emitted by the sub-pixel P and then reflected by the target object. For example, the stray light may be the light outside the display apparatus 1000, or the light emitted by the sub-pixel P and reflected by the second electrode, or the light emitted by the sub-pixel P that is not reflected by the target object and directly enters the light-absorbing pattern 303B. The more stray light there is, the greater the impact on the accuracy of the detection, recognition, or scanning and imaging of the photosensor M. In order to solve the above problems, the following embodiments are provided in the present disclosure.

In some embodiments, a ratio of an area of the first opening K1 to an area of the second opening K2 is in a range of approximately 1 to approximately 3.5. For example, the ratio of the area of the first opening K1 to the area of the second opening K2 is in a range of approximately 1.75 to approximately 2. For example, the ratio of the area of the first opening K1 to the area of the second opening K2 is approximately 1, 1.3, 1.75, 2, 2.05, 2.987, 3 or 3.5.

It will be noted that the “an area of the first opening K1” is an area of a section of the first opening K1 in a direction parallel to the substrate 21, and the “area of the second opening K2” is an area of a section of the second opening K2 in a direction parallel to the substrate 21.

For example, the area of the first opening K1 may be in a range of 64 μm² to 196 μm², such as 64 μm², 70 μm², 85 μm², 90.12 μm², 150.5 μm² or 196 μm².

For example, the area of the second opening K2 may be in a range of 16 μm² to 64 μm², such as 16 μm², 20 μm², 35 μm², 40.5 μm², 51.65 μm² or 64 μm².

By setting the ratio of the area of the first opening K1 to the area of the second opening K2 to be in a range of approximately 1 to approximately 3.5, the area of the second opening K2 is limited while achieving that the second opening K2 enable the light-absorbing pattern 303B to fully absorb the return light. Thus, it is possible to avoid the absorption for stray light to the greatest extent, for example, to prevent the stray light outside the display apparatus 1000 from entering the second opening K2 too much, thereby reducing the interference of stray light on the photosensor M during the function implementation process.

In some embodiments, as shown in FIG. 16, the display panel 100 further includes a first light-shielding pattern 401 and a cover plate 402.

Referring to FIG. 16, the cover plate 402 is disposed on a side of the second electrode layer 304 away from the substrate 21.

The cover plate 402 is configured to be installed with the U-shaped groove-shaped outer shell of the display apparatus 1000 to form a protective shell, and the structural components of the display apparatus 1000 are all located in the protective shell.

Referring to FIG. 16, the first light-shielding pattern 401 is disposed on the side of the second electrode layer 304 away from the substrate 21. The first light-shielding pattern 401 is disposed between the second electrode layer 304 and the cover plate 402.

For example, the first light-shielding pattern 401 and the cover plate 402 are attached together by an optical adhesive.

For example, the first light-shielding pattern 401 is configured to prevent stray light from outside the display apparatus 1000 from entering the display apparatus 1000, thereby reducing the interference of stray light on the light emission of the sub-pixel P, and reducing the interference of stray light on the light absorption of the photosensor M.

For example, a material of the first light-shielding pattern 401 may be a material that capable of absorbing visible light.

For example, the material of the first light-shielding pattern 401 includes a metal material, or includes a resin material doped with pigments (e.g., carbon black) or dyes, thereby achieving the purpose of light-shielding.

For example, the first light-shielding pattern 401 includes a red filter, a green filter and a blue filter that are stacked in a direction perpendicular to the substrate 21 to block external visible light.

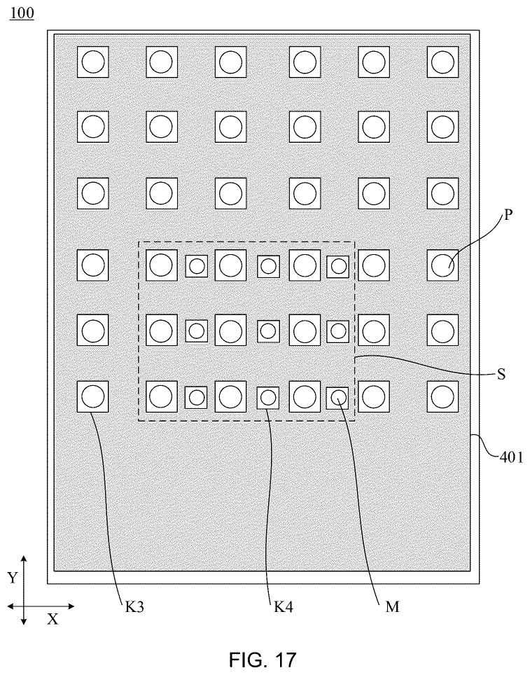

For example, referring to FIG. 17, the first light-shielding pattern 401 is provided on the entire screen; that is, in addition to a case that the functional device region S where the photosensors M are arranged is provided with the first light-shielding pattern 401, other regions of the display panel 100 are also provided with the first light-shielding pattern 401. Thus, it is possible to effectively improve the ability of the first light-shielding pattern 401 to insulate the light outside the display apparatus 1000, so as to improve the luminous display effect of the display apparatus 1000.

Referring to FIGS. 16 and 17, the first light-shielding pattern 401 is provided with a third opening K3 and a fourth opening K4 therein. The third opening K3 is disposed corresponding to the light-emitting pattern 303A, and the fourth opening K4 is disposed corresponding to the light-absorbing pattern 303B.

That is, the sub-pixel P is exposed by the third opening K3 to prevent the first light-shielding pattern 401 from blocking the light-emitting path of the sub-pixel P, and the photosensor M is exposed by the fourth opening K4 to prevent the first light-shielding pattern 401 from blocking the path of the photosensor M absorbing returned light (the light emitted by the sub-pixel P and then reflected by the target object).

With the above arrangement, while the light-emitting of the sub-pixels P is satisfied and the light absorption of the photosensors M is satisfied, the first light-shielding pattern 401 may prevent the light outside the display apparatus 1000 from entering the display panel 100 to reduce the impact of stray light on the sub-pixel P and the photosensor M, thereby improving the absorption efficiency of the light-absorbing pattern 303B for effective light, i.e., return light, and improving the sensitivity of the photosensors M.

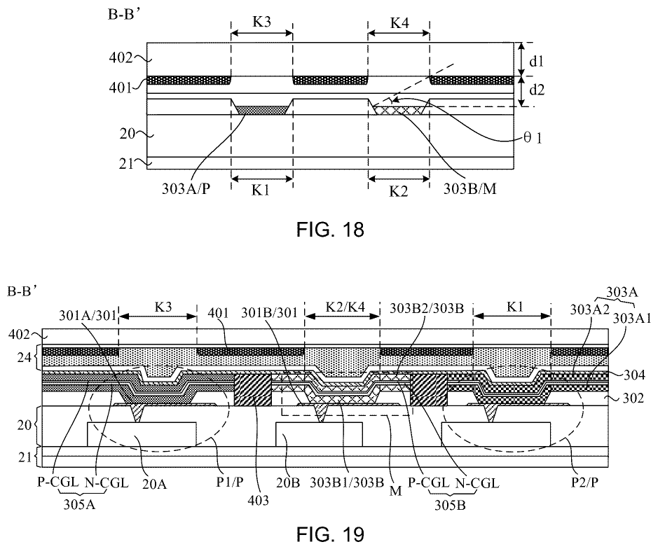

Based on the above embodiments, referring to FIG. 18, a ratio of a vertical distance d1 from a surface of the first light-shielding pattern 401 away from the substrate 21 to a surface of the cover plate 402 away from the substrate 21 to a vertical distance d2 from the surface of the first light-shielding pattern 401 away from the substrate 21 to the light-absorbing pattern 303B is in a range of approximately 1.8 to approximately 2.8. For example, the ratio is 1.8, 2, 2.56 or 2.8.

For example, the vertical distance d1 from the surface of the first light-shielding pattern 401 away from the substrate 21 to the surface of the cover plate 402 away from the substrate 21 may be 756 μm, 800.5 μm, 953.75 μm, or 1176 μm.

For example, the vertical distance d2 from the surface of the first light-shielding pattern 401 away from the substrate 21 to the light-absorbing pattern 303B may be 420 μm, 500.5 μm, or 653.33 μm.

According to the structure in the above embodiments, the target object is placed on a side of the cover plate 402 away from the substrate 21, and after passing through the first opening K1, the third opening K3 and the cover plate 402 in sequence, the light emitted by the sub-pixel P reaches the target object and is reflected by the target object to form return light; after passing through the cover plate 402, the fourth opening K4 and the second opening K2 in sequence, the return light reaches the light-absorbing pattern 303B, thereby realizing the light absorption of the photosensor M.

By setting the ratio of the vertical distance d1 to the vertical distance d2 to be in a range of approximately 1.8 to approximately 2.8, that is, by controlling a ratio of a distance between the target object and the first light-shielding pattern 401 to a distance between the light-absorbing pattern 303B and the first light-shielding pattern 401, under the condition that the size of the fourth opening K4 remains unchanged, it is possible to achieve the control of the amount of returned light that can reach the light-absorbing pattern 303B and achieve the control of the area of the effective region of the target object that the photosensor M can scan or recognize.

In some embodiments, as shown in FIG. 18, a minimum included angle θ1 between a connection line, between a side wall of the fourth opening K4 and the light-absorbing pattern 303B corresponding to the fourth opening K4, and the light-absorbing pattern 303B is in a range of approximately 40° to approximately 60°. For example, the minimum included angle θ1 is approximately 40°, 45°, 53.5°, 57.85° or 60°.

For example, there may be multiple connection lines between the side wall of the fourth opening K4 and the light-absorbing pattern 303B corresponding to the fourth opening K4. Among the multiple connection lines, a connection line that capable of forming the minimum angle θ1 with the light-absorbing pattern 303B is a connection line between the side wall of the fourth opening K4 and a position of the light-absorbing pattern 303B in contact with the side wall of the second opening K2 (referring to FIG. 18).

With the above arrangement, the ratio of the distance between the first light-shielding pattern 401 and the target object to the distance between the first light-shielding pattern 401 and the light-absorbing pattern 303B may be limited. Thus, under the condition that the size of the fourth opening K4 remains unchanged, it is possible to achieve the control of the amount of returned light that can reach the light-absorbing pattern 303B and the control of the area of the effective region of the target object that the photosensor M can scan or recognize.

In some embodiments, as shown in FIG. 19, the display panel 100 further includes second light-shielding patterns 403.

Referring to FIG. 19, the second light-shielding patterns 403 are disposed between the substrate 21 and the second electrode layer 304.

The second light-shielding pattern 403 may be configured to absorb the light emitted by the sub-pixel P and reflected by the second electrode layer 304. The light does not pass through the target object and therefore carries no information about the target object; when the light is incident on the light-absorbing pattern 303B, it will interfere with the recognition process of the photosensor M. By setting the second light-shielding pattern 403, the amount of stray light in this part may be effectively reduced, thereby improving the recognition accuracy of the photosensor M.

Referring to FIG. 19, the second light-shielding pattern 403 is located between the light-absorbing pattern 303B and the light-emitting pattern 303A adjacent to the light-absorbing pattern 303B.

The second light-shielding pattern 403 may be further configured to avoid interference with the recognition and detection process of the photosensor M caused by a fact that the light emitted by the sub-pixel P directly reaches the light-absorbing pattern 303B without reflection. By setting the second light-shielding pattern 403 between the light-absorbing pattern 303B and the light-emitting pattern 303A, the second light-shielding pattern 403 may block the light emitted by the sub-pixel P from directly irradiating the light-absorbing pattern 303B in a direction parallel to the substrate 21, thereby reducing the amount of stray light and improving the function realization effect of the photosensor M.

Referring to 19, a vertical distance from a surface of the second light-shielding pattern 403 away from the substrate 21 to the substrate 21 is greater than or equal to both a vertical distance from a surface of the light-absorbing pattern 303B away from the substrate 21 to the substrate 21 and a vertical distance from a surface of the light-emitting pattern 303A away from the substrate 21 to the substrate 21. The vertical distance from the surface of the second light-shielding pattern 403 away from the substrate 21 to the substrate 21 is greater than or equal to a vertical distance from a surface of a portion of the light-absorbing pattern 303B located in the second opening K2 away from the substrate 21 to the substrate 21, and is greater than or equal to a vertical distance from a surface of a portion of the light-emitting pattern 303A located in the first opening K1 away from the substrate 21 to the substrate 21.

That is, in the direction perpendicular to the substrate 21, the second light-shielding pattern 403 is higher than a plane where the light-absorbing pattern 303B and the light-emitting pattern 303A are located, thereby ensuring that the light emitted by the sub-pixel P and transmitted substantially in a direction parallel to the substrate 21 is able to be fully blocked by the second light-shielding pattern 403, so as to reduce the interference of stray light on the photosensor M.

It will be noted that the second light-shielding pattern 403 is disposed between the substrate 21 and the second electrode layer 304, and the specific position of the film layer where the second light-shielding pattern 403 is arranged is not limited in the present disclosure.

For example, the second light-shielding pattern 403 may be disposed on a side of the pixel definition layer 302 away from the substrate 21. For example, the second light-shielding pattern 403 is disposed between the pixel definition layer 302 and the second electrode layer 304.

Alternatively, for example, the second light-shielding pattern 403 is disposed on a film layer where the pixel definition layer 302 is located; that is, the second light-shielding pattern 403 is embedded in the pixel definition layer 302.

Alternatively, for example, referring to FIG. 19, the second light-shielding pattern 403 is disposed between a side of the first electrode layer 301 proximate to the substrate and the second electrode layer 304; that is, the second light-shielding pattern 403 penetrates the first electrode layer 301 and the pixel definition layer 302, thereby further enhancing the blocking effect of the second light-shielding pattern 403 on the light emitted by the sub-pixel P and transmitted substantially in the direction parallel to the substrate 21 to reduce the interference of stray light on the photosensor M.

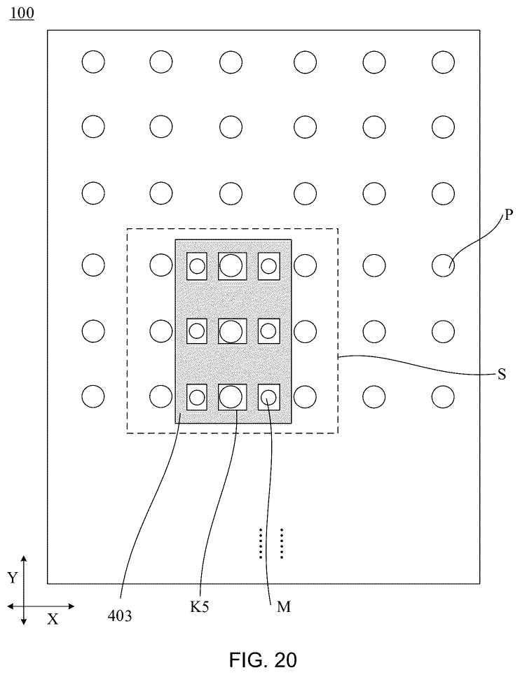

In some embodiments, as shown in FIG. 20, the second light-shielding pattern 403 is arranged in the functional device region S where the photosensors M are provided of the display panel 100, thereby ensuring the ability of the second light-shielding pattern 403 to block stray light to improve the function realization effect of photosensors M.

In some embodiments, as shown in FIG. 20, an orthographic projection of the second light-shielding pattern 403 on the substrate 21 avoids the orthogonal projections of the first opening K1 and the second opening K2 on the substrate 21. That is, it is possible to prevent the second light-shielding pattern 403 from blocking the path of the light emitted by the sub-pixel P, and prevent the second light-shielding pattern 403 from blocking the path of the photosensor M to absorb the return light.

For example, referring to FIG. 20, the second light-shielding pattern 403 may be in a one-piece structure, the second light-shielding pattern 403 is provided with a plurality of fifth openings K5 therein, and the fifth opening K5 is arranged corresponding to the first opening K1 or to the second opening K2, thereby preventing the second light-shielding pattern 403 from blocking the light-emitting path of the sub-pixel P and the light-absorbing path of the photosensor M while the blocking effect of the second light-shielding pattern 403 on stray light is achieved.

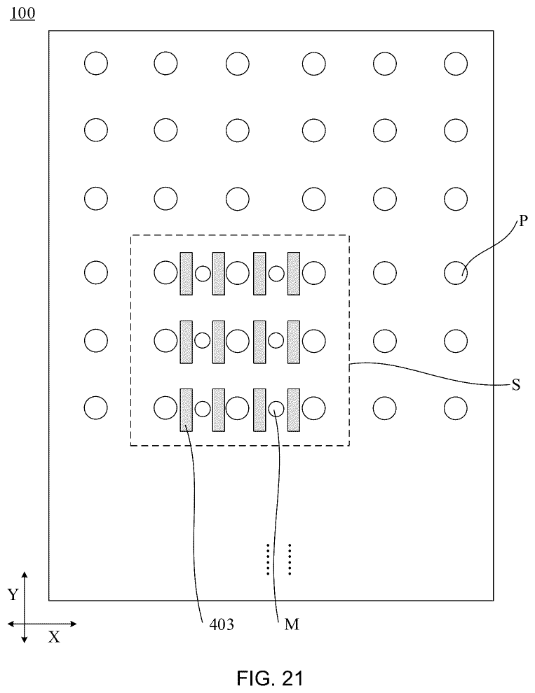

For example, referring to FIG. 21, the display panel 100 includes a plurality of second light-shielding patterns 403, and each second light-shielding pattern 403 is disposed between the photosensor M and the sub-pixel P.

In some embodiments, as shown in FIGS. 14 and 15, the display panel 100 further includes an encapsulation layer 113 disposed on a side of the second electrode layer 304 away from the substrate 21.

A refractive index of the encapsulation layer 24 is in a range of 1.5 to 1.8. For example, the refractive index of the encapsulation layer 24 may be 1.5, 1.56, 1.652, 1.7, or 1.8.

For example, the encapsulation layer 24 includes a first encapsulation sub-layer, a second encapsulation sub-layer, and a third encapsulation sub-layer that are stacked in a direction of away from the substrate 21. For example, materials of the first encapsulation sub-layer and the third encapsulation sub-layer include an inorganic material, and a material of the second encapsulation sub-layer includes an organic material. The first encapsulation sub-layer and the third encapsulation sub-layer have a function of blocking moisture and oxygen, and the second encapsulation sub-layer has certain flexibility and a function of absorbing moisture.

For example, as shown in FIG. 16, the first light-shielding pattern 401 may be disposed in the encapsulation layer 24.

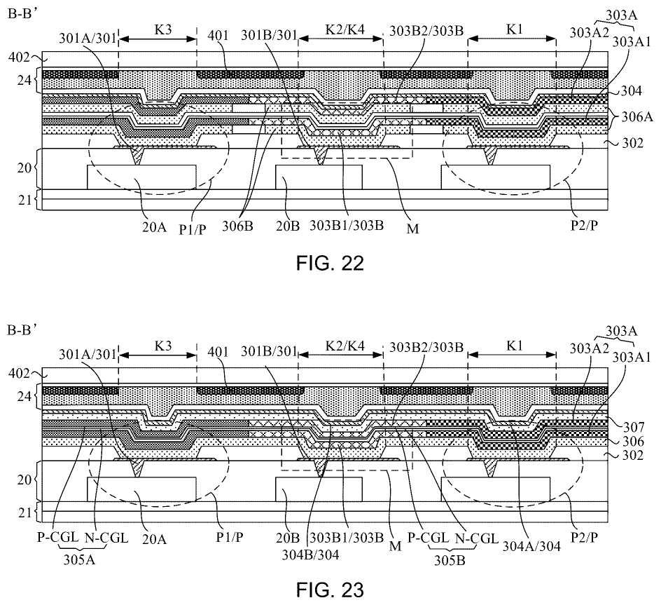

In some embodiments, as shown in FIG. 22, the display panel 100 further includes a second hole transport pattern 306B disposed between the second anode 301B and the light-absorbing pattern 303B. The second hole transport pattern 306B is configured to improve the conduction efficiency of carriers in the light-absorbing pattern 303B in an electric field formed between the second anode 301B and the second electrode layer 304.

For example, in the case where the light-absorbing pattern 303B includes a plurality of light-absorbing sub-patterns 303B′, each light-absorbing sub-pattern 303B′ is provided with a second hole transport pattern 306B on a side thereof proximate to the substrate 21.

For example, referring to FIG. 22, in the case where the light-absorbing pattern 303B includes a first light-absorbing sub-pattern 303B1 and a second light-absorbing sub-pattern 303B2, and the first light-absorbing sub-pattern 303B1 is closer to the substrate 21 than the second light-absorbing sub-pattern 303B2, the display panel 100 includes two second hole transport patterns 306B, in which one second hole transport pattern 306B is disposed between the first light-absorbing sub-pattern 303B1 and the second light-absorbing sub-pattern 303B2, and the other second hole transport pattern 306B is disposed between the first light-absorbing sub-pattern 303B1 and the second anode 301B. Thus, it is possible to further improve the conduction efficiency of carriers in the light-absorbing pattern 303B, thereby improving the function realization effect of the photosensor M, for example, improving the fingerprint recognition speed.

In some embodiments, as shown in FIG. 22, the display panel 100 further includes a first hole transport pattern 306A disposed between the first anode 301A and the light-emitting pattern 303A. The first hole transport pattern 306A is configured to improve the conduction efficiency of carriers in the light-emitting pattern 303A in an electric field formed between the first anode 301A and the second electrode layer 304.

For example, in the case where the light-absorbing pattern 303B includes a plurality of light-absorbing sub-patterns 303B′, each light-absorbing sub-pattern 303B′ is provided with a second hole transport pattern 306B on a side thereof proximate to the substrate 21.

For example, referring to FIG. 22, in the case where the light-emitting pattern 303A includes a first light-emitting sub-pattern 303A1 and a second light-emitting sub-pattern 303A2, and the first light-emitting sub-pattern 303A1 is closer to the substrate 21 than the second light-emitting sub-pattern 303A2, the display panel 100 includes two first hole transport patterns 306A, in which one first hole transport pattern 306A is disposed between the first light-emitting sub-pattern 303A1 and the second light-emitting sub-pattern 303A2, and the other first hole transport pattern 306A is disposed between the first light-emitting sub-pattern 303A1 and the first anode 301A. Thus, it is possible to further improve the conduction efficiency of carriers in the light-emitting pattern 303A, thereby improving the luminous display effect of the sub-pixel P.

For example, the sub-pixels P capable of emitting light of different colors respectively correspond to different first hole transport patterns 306A, thereby achieving control of the transport characteristics of carriers in the sub-pixels P emitting different colors.

A material of the first hole transport pattern 306A is different from the material of the second hole transport pattern 306B. Thus, the carriers in the sub-pixel P and the photosensor M may be controlled separately.

In some embodiments, the display panel 100 further includes a first common layer 306, or the display panel 100 further includes a second common layer 307, or as shown in FIG. 23, the display panel 100 includes both the first common layer 306 and the second common layer 307.

Referring to FIG. 23, the first common layer 306 is disposed between the first anode 301A and the light-emitting pattern 303A and between the second anode 301B and the light-absorbing pattern 303B.

The first common layer 306 includes a hole transport layer and/or a hole injection layer. The first common layer 306 is configured to improve the conduction efficiency of carriers (e.g., holes) between the first anode 301A and the light-emitting pattern 303A and improve the conduction efficiency of carriers (e.g., holes) between the second anode 301B and the light-absorbing pattern 303B, thereby enhancing the luminous display effect of the sub-pixel P and the function realization effect of the photosensor M.

Referring to FIG. 23, the second common layer 307 is disposed between the light-emitting pattern 303A and the second electrode layer 304, and between the light-absorbing pattern 303B and the second electrode layer 304.

The second common layer 307 includes an electron transport layer and/or an electron injection layer. The second common layer 307 is configured to improve the conduction efficiency of carriers (e.g., electrons) between the light-emitting pattern 303A and the second electrode layer 304 and improve the conduction efficiency of carriers (e.g., electrons) between the light-absorbing pattern 303B and the second electrode layer 304, thereby also enhancing the luminous display effect of the sub-pixel P and the function realization effect of the photosensor M.

In some embodiments, the display panel 100 further includes a driving signal line, an end of the driving signal line is electrically connected to the second anode 301B, and the other end of the driving signal line is electrically connected to an external processor. The driving signal line is configured to transmit a second anode signal to the second anode 301B.

The processor is configured to be electrically connected to the photosensor M through the driving signal line, thereby driving the photosensor M to absorb light and to perform processes such as recognize or image the information carried by the absorbed light. That is, the information carried by the return light received by the photosensor M is analyzed and processed through the external structure.

In some other embodiments, the structure for driving the photosensor M to absorb light and analyzing and processing the information carried by the absorbed light may be disposed inside the display panel 100.

In some embodiments, as shown in FIGS. 14, 15, and 24, the display panel 100 further includes an circuit layer 20 disposed between the substrate 21 and the first electrode layer 301.

The circuit layer 20 includes pixel circuits 20A and a photosensitive driving circuit 20B. The pixel circuit 20A is electrically connected to the first anode 301A, and the photosensitive driving circuit 20B is electrically connected to the second anode 301B. The pixel circuit 20A is configured to drive the sub-pixel P to emit light for display, and the photosensitive driving circuit 20B is configured to drive the photosensor M to absorb light.

In the above embodiments, the structure (i.e., the photosensitive driving circuit 20B) for driving the photosensor M to absorb light is arranged in the screen, which may improve the utilization rate of the internal space of the display panel 100 and increase the driving speed of the photosensor M to optimize the function implementation effect of the photosensor M.

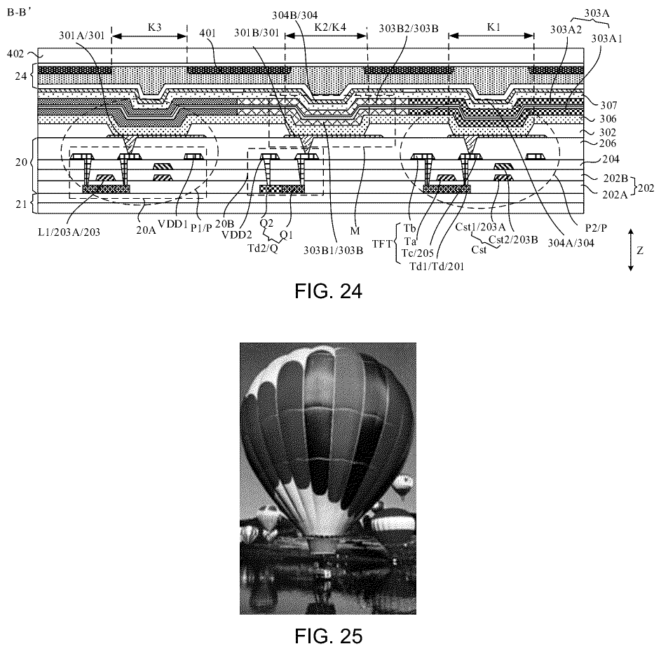

In some embodiments, as shown in FIG. 24, the circuit layer 20 includes an active layer 201, a gate insulating layer 202, a gate conductive layer 203, an interlayer dielectric layer 204, and a source-drain conductive layer 205 that are arranged in a direction Z perpendicular to the substrate 21 and away from the substrate 21.

For example, the gate conductive layer 203 includes at least one layer, and correspondingly, the gate insulating layer 202 also includes at least one layer. For example, referring to FIG. 24, the gate conductive layer 203 includes a first gate conductive layer 203A and a second gate conductive layer 203B. Correspondingly, the gate insulating layer 202 includes a first gate insulating layer 202A and a second gate insulating layer 202B.

For example, the source-drain conductive layer 205 may include multiple layers. For example, the source-drain conductive layer 205 includes a first source-drain conductive layer and a second source-drain conductive layer.

For example, referring to FIG. 24, the circuit layer 20 further includes a planarization layer 206 disposed between the source-drain conductive layer 205 and the first electrode layer 301.

For example, in a case where the source-drain conductive layer 205 includes the first source-drain conductive layer and the second source-drain conductive layer, the planarization layer 206 includes a first planarization layer and a second planarization layer. The first planarization layer serves as an insulating medium and is disposed between the first source-drain conductive layer and the second source-drain conductive layer, and the second planarization layer is disposed between the second source-drain conductive layer and the first electrode layer 301.

For example, the circuit layer 20 further includes a passivation layer; and the passivation layer is disposed on a side of the source-drain conductive layer away from the substrate 21, and is configured to prevent the metal structure in the source-drain conductive layer from being corroded and damaged.

Referring to FIG. 24, the driving circuit 20 is provided with a plurality of transistors TFT and a plurality of capacitor structures Cst therein. The pixel circuit 20A corresponding to each sub-pixel P includes at least one transistor TFT and at least one capacitor structure Cst. Only one transistor TFT and corresponding capacitor structures Cst are illustrated in FIG. 24.

The capacitor structure Cst may include a first plate Cst1 and a second plate Cst2, the first plate Cst1 is located in the first gate conductive layer 203A, and the second plate Cst2 is located in the second gate conductive layer 203B.

The transistor TFT includes a gate Ta, a source Tb, a drain Tc, and an active layer pattern Td. The source Tb and the drain Tc are in contact with the active layer pattern Td.

The active layer pattern Td is configured to form a channel under control of the gate Ta, so that the source Tb and the drain Tc that are connected to the active layer pattern Td are conductive to turn on the transistor TFT. For example, the transistor TFT further includes a portion of the first gate insulating layer 202 located between a film layer where the gate Ta is located and a film layer where the active layer pattern Td is located.

It will be noted that, a control electrode of each transistor TFT is a gate Ta of the transistor, a first electrode of the transistor TFT is one of a source Tb and a drain Tc of the transistor, and a second electrode of the transistor TFT is the other of the source Tb and the drain Tc of the transistor. Since the source Tb and the drain Tc of the transistor TFT may be symmetrical in structure, there may be no difference in structure between the source Tb and the drain Tc.

For example, as shown in FIG. 24, the pixel circuit 20A includes a first active layer pattern Td1, a scan signal line L1, and a first power supply line VDD1.

The first active layer pattern Td1 is located in the active layer 201, and the scan signal line L1 is located in the gate conductive layer 203, for example, located in the first gate conductive layer 203A.

Overlapping portions of the first active layer pattern Td1 and the scan signal line L1 form a part of a transistor TFT. A portion of the scan signal line L1 overlapping with the first active layer pattern Td1 serves as the gate Ta of the transistor TFT, and portions, at two ends, of a portion of the first active layer pattern Td1 overlapping with the scan signal line L1 are in contact with the source Tb and the drain Tc of the transistor TFT.

For example, the pixel circuit 20A may further include other signal lines, for example, may further include an enable signal line or an initialization signal line. These signal lines overlap with the active layer pattern Td located in the active layer 201 to form transistors that capable of transmitting different signals.

At least one transistor TFT is electrically connected to the first anode 301A. The first anode 301A may be electrically connected to the source Tb or the drain Tc of the transistor TFT, so that the light-emitting pattern 303A emits light under control of the transistor TFT.

Referring to FIG. 24, the first power supply line VDD1 is located in the source-drain conductive layer 205. The first power supply line VDD1 is configured to provide a first power signal to the sub-pixel P, thereby driving the sub-pixel P to emit light for display.

The first power supply line VDD1 is electrically connected to at least one transistor TFT to provide a power supply signal to the transistor TFT, and then to transmit the power supply signal to the first anode 301A through the transistor TFT, so as to achieve the luminous display of the sub-pixel P.

In some embodiments, as shown in FIG. 24, the photosensitive driving circuit 20B in the circuit layer 20 includes a diode Q and a second power supply line VDD2.

Referring to FIG. 24, the second power supply line VDD2 is located in the source-drain conductive layer 205. The second power supply line VDD2 is configured to provide a second power supply signal to the photosensor M, thereby driving the photosensor M to perform functions such as recognition, detection, or scanning and imaging.

An end of the diode Q is electrically connected to the second anode 301B, and the other end of the diode Q is electrically connected to the second power supply line VDD2. Thus, the second power supply line VDD2 may smoothly transmit the second power supply signal to the second anode 301B to achieve the light absorption of the photosensor M.

For example, the diode Q is a backflow prevention diode, which may avoid the problem that the structure in the photosensor M is heated or even damaged due to reverse current transmission.

In some embodiments, as shown in FIG. 24, the diode Q includes a second active layer pattern Td2 located in the active layer 201.

Referring to FIG. 24, the second active layer pattern Td2 includes a first portion Q1 and a second portion Q2 that are electrically connected. The first portion Q1 is a hole-type semiconductor, and the second portion Q2 is an electron-type semiconductor. For example, a material of the first portion Q1 is P-type silicon (P—Si), and a material of the second portion Q2 is N-type silicon (N—Si).

The first portion Q1 is electrically connected to the second anode 301B, and the second portion Q2 is electrically connected to the second power supply line VDD2. Thus, the second power supply line VDD2 may transmit the second power supply signal to the second anode 301B, so that the photosensor M may realize functions such as recognition, detection or scanning recognition. Moreover, by setting the second power supply line VDD2 to be electrically connected to the second portion Q2, it is possible to achieve the function of backflow prevention.

In some embodiments, as shown in FIGS. 23 and 24, the second electrode layer 304 includes first cathodes 304A and a second cathode 304B. The first cathode 304A corresponds to the light-emitting pattern 303A, and the second cathode 304B corresponds to the light-absorbing pattern 303B.

For example, as shown in FIG. 24, the first cathode 304A and the second cathode 304B are insulated from each other, and the first cathode 304A and the second cathode 304B are configured to respectively transmit different cathode signals.

The second electrode layer 304 is set to include first cathodes 304A and second cathode(s) 304B that are insulated from each other, so that the second electrode layer 304 may transmit different cathode signals to the sub-pixel P and the photosensor M respectively, so as to achieve the independent control of the sub-pixel P and the photosensor M.

For example, a cross voltage between the first anode 301A and the first cathode 304A is in a range of approximately 8 V to approximately 16 V, such as 8 V, 10.5 V, 13.56 V or 16 V. The cross voltage of the sub-pixel P (i.e., a voltage difference between the first anode 301A and the first cathode 304A) may be adjusted by setting the voltage of the first cathode 304A.

For example, the cross voltage between the second anode 301B and the second cathode 304B is in a range of approximately-2 V to approximately 8 V, such as −2 V, 0 V, 1.5 V, 4.75 V or 8 V. The cross voltage of the sub-pixel P (i.e., a voltage difference between the second anode 301B and the second cathode 304B) may be adjusted by setting the voltage of the second cathode 304B.

For example, as shown in FIG. 23, the first cathodes 304A and the second cathode 304B are in a one-piece structure, that is, the second electrode layer 304 is provided as a whole layer. In this case, the sub-pixels P and the photosensor(s) M share the second electrode layer 304, that is, the cathode voltage signals of the sub-pixels P and the photosensor(s) M are the same.

On this basis, by controlling the magnitude of the power supply signal transmitted by the first power supply line VDD1 and the second power supply line VDD2, the first anode 301A and the second anode 301B have different voltages respectively, i.e., the sub-pixel P and the photosensor M have different cross voltages, thereby achieving separate control of the sub-pixel P and the photosensor M.

For example, in a case where the second electrode layer 304 is of a one-piece structure and the cathode voltage is 0 V, the voltage of the first anode 301A may be controlled to be 8 V and the voltage of the second anode 301B may be controlled to be 1 V, thereby achieving separate control of cross voltages of the sub-pixel P and the photosensor M.

For example, the voltage between the first anode 301A and the second electrode layer 304 may be in a range of 8 V to 16 V, such as 8 V, 10.5 V, 13.56 V or 16 V; the voltage between the second anode 301B and the second electrode layer 304 may be in a range of −2 V to 8 V, such as −2 V, 0 V, 1.5 V, 4.75 V or 8 V.

The inventors of the present disclosure have analyzed the function realization effect of the display apparatus 1000 provided by the embodiments of the present disclosure, and the analysis results are as follows.

TABLE 1

| | | | | Imaging |
|---|---|---|---|---|
| Recognition | | Imaging | | experimental |
| project | Value | project | Value | products |
| Recognition | >600 ppi | Sensor | >1302 dpi | 4334 dpi |
| resolution | | resolution | | |
| Effective | 38° | θ1 | 52° | |
| imaging | | | | |
| angle | | | | |
| Recognition | Approximately | Imaging | 656 μm | |
| size | 1423 μm | size | | |
| Line width | Approximately | Pixel | <19.3 μm | 5.86 μm |
| of ridge- | 500 μm | size | | |
| valley | | | | |
| Recognized | Approximately | Contained | >33 | Approximately |
| ridge- | 2.8 pairs | pixels | | 120 |
| valley | | | | |
| line pairs | | | | |

Referring to Table 1, the inventors of the present disclosure have conducted corresponding analyses on the fingerprint recognition items and the scanning and imaging items of the photosensor M. “Recognition project” means that only the target object needs to be detected and recognized, for example, the light emitted by the sub-pixel P is irradiated onto the finger and then reflected by the finger to form a return light, and the photosensor M absorbs the return light and compares the fingerprint information carried by the return light to realize the recognition of the finger fingerprint. “Imaging project” means that the target object is scanned and the scanned information is displayed as an image; for example, the light emitted by the sub-pixel P is irradiated onto the picture and is reflected by the picture to form return light; the return light carries position information and color information of the picture; the photosensor M absorbs the returned light and displays the position information and color information of the picture carried by the returned light in the form of an image, thereby completing the scanning and imaging of the picture.

According to Table 1, it can be seen that in the recognition project, a recognition resolution of the photosensor M of the display apparatus 1000 provided by the embodiments of the present disclosure may reach more than 600 ppi; in a case where the effective imaging angle is 38°, the recognition size (e.g., a side length of a region of a finger that can be recognized by the photosensor M) is approximately 1423 μm, in the fingerprint recognition project, there are approximately 2.8 pairs of ridge-valley lines that can be identified.

According to Table 1, it can be seen that in the recognition project, for the photosensor M of the display apparatus 1000 provided by the embodiments of the present disclosure, the resolution of the photosensor M during the scanning and imaging process can reach more than 1302 dpi, such as 4334 dpi; and thus, the side length of the image after imaging and imaging by the photosensor M may reach 656 μm, and each pixel may be less than 19.3 μm, such as 5.86 μm, and the number of pixels may reach more than 33, such as 120.

The inventors of the present disclosure analyzed the scanning and imaging function of the display apparatus 1000 provided by the embodiments of the present disclosure.

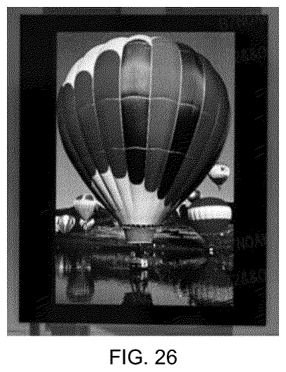

FIG. 25 is a picture of a target object, and the display apparatus 1000 provided by the embodiments of the present disclosure performing scanning and imaging on the picture. For example, the display side of the display apparatus 1000 is facing the picture, the light emitted by the sub-pixel P is used as a light source to capture the picture, and the photosensor M receives the photographing result and performs imaging to obtain an image as shown in FIG. 26.

Referring to FIG. 26, it can be seen that the image obtained after scanning and imaging by the display apparatus 1000 provided by the embodiments of the present disclosure has high resolution, and the color saturation and color accuracy are substantially the same as that of the picture in FIG. 25. That is, the image provided by the embodiment of the present disclosure the effect of scanning and imaging of the display apparatus 1000 is realistic.

In another aspect, some embodiments of the present disclosure provide a display panel 100.

As shown in FIG. 16, the display panel 100 includes a substrate 21, a first electrode layer 301, a pixel definition layer 302, a light-emitting pattern 303A, a light-absorbing pattern 303B, a second electrode layer 304, a first light-shielding pattern 401, and a cover plate 402.

The substrate 21 may be of a single-layer structure or a multi-layer structure. For example, the substrate 21 includes a flexible base layer and a buffer layer that are stacked sequentially. For another example, the substrate 21 includes a plurality of flexible base layers and a plurality of buffer layers arranged alternately. A material of the flexible base layer may include polyimide, and a material of the buffer layer may include silicon nitride and/or silicon oxide, so as to achieve an effect of blocking moisture, oxygen and alkaline ions.

Referring to FIG. 16, the first electrode layer 301 is disposed on a side of the substrate 21.

The first electrode layer 301 includes a first anode 301A and a second anode 301B. The first anode 301A and the second anode 301B are configured to transmit different anode signals, respectively.

For example, the first anode 301A and the second anode 301B are all configured to transmit a high-level voltage, for example, configured to transmit a power supply voltage.

Referring to FIG. 16, the pixel definition layer 302 is disposed on a side of the first electrode layer away from the substrate 21. The pixel definition layer 302 is provided with a first opening K1 and a second opening K2 therein. The first opening K1 corresponds in position to the first anode 301A, and the second opening K2 corresponds in position to the second anode 301B.

Referring to FIG. 16, at least portion of the light-emitting pattern 303A is disposed in the first opening K1.

For example, the portion of the light-emitting pattern 303A located in the first opening K1 is in electrical contact with the first anode 301A.

A material of the light-emitting pattern 303A may be fluorescent luminescent material or a phosphorescent luminescent material, which is capable of emitting red light, blue light, green light or white light.

The light-emitting pattern 303A is configured as a light-emitting material of the sub-pixel P in the display panel 100, so that the luminous display of the display panel 100 is achieved.

Referring to FIG. 16, at least portion of the light-absorbing pattern 303B is disposed in the second opening K2.

For example, the portion of the light-absorbing pattern 303B located in the second opening K2 is in electrical contact with the second anode 301B.

For example, the light-absorbing pattern 303B is capable of absorbing the light.

For example, in a case where the light-absorbing pattern 303B is configured to form the photosensor M described in the above embodiments, the light-absorbing pattern 303B is capable of absorbing the light emitted by the light-emitting pattern 303A. For example, the light-absorbing pattern 303B is capable of absorbing the light directly emitted by the light-emitting pattern 303A, and is capable of absorbing the light that is emitted by the light-emitting pattern 303A and then reflected by the target object or other structures.

In the case where the light-absorbing pattern 303B forms the photosensor M, its characteristics and effects are substantially the same as those of the display panel 100 provided in any of the above embodiments, and will not be repeated here.

Alternatively, for example, in a case where the light-absorbing pattern 303B is configured as a light-shielding material to absorb stray light to prevent the stray light from affecting the light-emitting effect of the sub-pixel P, the light-absorbing pattern 303B is capable of absorbing ambient light entering the display panel 100 from outside the display panel 100, thereby preventing ambient light from affecting the luminous accuracy of the sub-pixel P. Alternatively, the light-absorbing pattern 303B is capable of absorbing stray light that is emitted by the sub-pixel P and repeatedly reflected inside the display panel 100, thereby also improving the light-emitting effect of the sub-pixel P, for example, improving the accuracy of the color of the light emitted by the sub-pixel P.

Referring to FIG. 16, the second electrode layer 304 is disposed on a side of the pixel definition layer 302 away from the substrate 21 and covers the light-emitting pattern 303A and the light-absorbing pattern 303B.

For example, the second electrode layer 304 is configured to transmit a low-level voltage.

An electric field is developed due to the combined action of the high-level voltage transmitted by the first anode 301A and the low-level voltage transmitted by the portion of the second electrode layer 304 covering the light-emitting pattern 303A. Under the driving of the electric field, the holes in the first anode 301A and the electrons in the second electrode layer 304 are all transmitted to the light-emitting pattern 303A located in the first opening K1, and the holes and electrons combine in the light-emitting pattern 303A to form excitons to emit light.

The light emitted by the light-emitting pattern 303A is emitted through the first opening K1, that is, a region where the first opening K1 is located is an effective light-emitting region of the sub-pixel P.

In the case where the light-absorbing pattern 303B is configured to form the photosensor M described in the above embodiments, the light-absorbing pattern 303B generates photo-induced carriers after absorbing light (for example, light emitted by the light-emitting pattern 303A and then reflected by the target object). An electric field is developed due to the combined action of the high-level voltage transmitted by the second anode 301B and the low-level voltage transmitted by the portion of the second electrode layer 304 covering the light-absorbing pattern 303B. Due to the action of the electric field, it is possible to achieve the transmission and analysis of the photo-induced carriers, so as to achieve optical detection, optical recognition, and scanning and imaging.

After being emitted by the light-emitting pattern 303A is irradiated onto the target object and is reflected by the target object, the light is incident on the light-absorbing pattern 303B through the second opening K2. That is, a region where the second opening K2 is located is an effective light-absorbing region of the photosensor M.

Referring to FIG. 16, the first light-shielding pattern 401 is disposed on the side of the second electrode layer 304 away from the substrate 21.

A material of the first light-shielding pattern 401 is a light-shielding material, for example, may be a material that capable of absorbing visible light, or may be a metal material, or a resin material doped with pigments (e.g., carbon black) or dyes, so as to achieve the purpose of light-shielding.

The first light-shielding pattern 401 is configured to prevent stray light from outside the display panel 100 from entering the display panel 100, thereby reducing the interference of stray light on the light emission of the light-emitting pattern 303A in the display panel 100, and reducing the interference of stray light on the light absorption of the light-absorbing pattern 303B in the display panel 100.

For example, in the case where the light-absorbing pattern 303B is configured to form the photosensor M described in the above embodiments, referring to FIGS. 16 and 17, the first light-shielding pattern 401 is provided with a third opening K3 and a fourth opening K4 therein. The third opening K3 is disposed corresponding to the light-emitting pattern 303A, and the fourth opening K4 is disposed corresponding to the light-absorbing pattern 303B.

That is, the sub-pixel P is exposed by the third opening K3 to prevent the first light-shielding pattern 401 from blocking the light-emitting path of the sub-pixel P, and the photosensor M is exposed by the fourth opening K4 to prevent the first light-shielding pattern 401 from blocking the path of the photosensor M absorbing returned light (the light that is emitted by the sub-pixel P and then reflected by the target object).

The third opening K3 and the fourth opening K4 is disposed in the first light-shielding pattern 401. Thus, the first light-shielding pattern 401 may block stray light outside the display panel 100 to prevent stray light from entering the display panel 100 to interfere with the light-emitting effect of the light-emitting pattern 303A and the light-absorbing effect of the light-absorbing pattern 303B, and moreover, it is possible to prevent the first light-shielding pattern 401 from blocking the light-emitting path of the light-emitting pattern 303A and prevent the first light-shielding pattern 401 from blocking the light-absorbing path of the light-absorbing pattern 303B, so that the luminous display function and the light absorption function of the display panel 100 is satisfied, and the luminous display effect of the sub-pixel P and the functions (e.g., scanning and imaging, recognition, and detection) of the photosensor M are improved.

The cover plate 402 is disposed on a side of the first light-shielding pattern 401 away from the substrate 21.

That is, the cover plate 402 is disposed on the display side of the display panel 100. The cover plate 402 is configured to protect the display screen of the display panel 100 and reduce the degree of damage to the display screen after being bumped by external forces.

Referring to FIG. 18, a ratio of a vertical distance d1 from a surface of the first light-shielding pattern 401 away from the substrate 21 to a surface of the cover plate 402 away from the substrate 21 to a vertical distance d2 from the surface of the first light-shielding pattern 401 away from the substrate 21 to the light-absorbing pattern 303B is in a range of approximately 1.8 to approximately 2.8. For example, the ratio is 1.8, 2, 2.56 or 2.8.

For example, the vertical distance d1 from the surface of the first light-shielding pattern 401 away from the substrate 21 to the surface of the cover plate 402 away from the substrate 21 may be 756 μm, 800.5 μm, 953.75 μm, or 1176 μm.

For example, the vertical distance d2 from the surface of the first light-shielding pattern 401 away from the substrate 21 to the light-absorbing pattern 303B may be 420 μm, 500.5 μm, or 653.33 μm.

In a case where the light-absorbing pattern 303B is configured to form the photosensor M described in the above embodiments, the target object is placed on a side of the cover plate 402 away from the substrate 21, and after passing through the first opening K1, the third opening K3 and the cover plate 402 in sequence, the light emitted by the light-emitting pattern 303A reaches the target object and is reflected by the target object to form return light; after passing through the cover plate 402, the fourth opening K4 and the second opening K2 in sequence, the return light reaches the light-absorbing pattern 303B, thereby realizing the light absorption of the photosensor M.

By setting the ratio of the vertical distance d1 to the vertical distance d2 to be in a range of approximately 1.8 to approximately 2.8, that is, by controlling a ratio of a distance between the target object and the first light-shielding pattern 401 to a distance between the light-absorbing pattern 303B and the first light-shielding pattern 401, under the condition that the size of the fourth opening K4 remains unchanged, it is possible to achieve the control of the amount of returned light that can reach the light-absorbing pattern 303B and achieve the control of the area of the effective region of the target object that the photosensor M can scan or recognize.

The above are only specific embodiments of the present disclosure, but the scope of protection of the present disclosure is not limited thereto, and any person skilled in the art may conceive of variations or replacements within the technical scope of the present disclosure, which shall fall within the protection scope of the present disclosure. Therefore, the protection scope of the present disclosure should be determined by the protection scope of the claims.

1. A display panel, comprising:
a substrate;
a first electrode layer disposed on a side of the substrate, wherein the first electrode layer includes first anodes and at least one second anode, and a first anode and a second anode are configured to respectively transmit different anode signals;
a pixel definition layer disposed on a side of the first electrode layer away from the substrate, wherein the pixel definition layer is provided with first openings and at least one second opening therein, and a first opening corresponds in position to the first anode, and a second opening corresponds in position to the second anode;
light-emitting patterns, wherein at least portion of a light-emitting pattern is located in the first opening;
at least one light-absorbing pattern, wherein at least portion of a light-absorbing pattern of the at least one light-absorbing pattern is located in the second opening; and
a second electrode layer disposed on a side of the pixel definition layer away from the first electrode layer and covering the light-emitting patterns and the at least one light-absorbing pattern;
wherein the display panel comprises a plurality of sub-pixels and at least one photosensor, each photosensor is arranged adjacent to at least one sub-pixel; a sub-pixel includes the first anode, the light-emitting pattern and a portion of the second electrode layer covering the light-emitting pattern, and a photosensor of the at least one photosensor includes the second anode, the light-absorbing pattern and a portion of the second electrode layer covering the light-absorbing pattern.

2. The display panel according to claim 1, wherein the light-absorbing pattern includes a plurality of light-absorbing sub-patterns that are sequentially arranged in a direction perpendicular to the substrate, and each light-absorbing sub-pattern is capable of absorbing light of at least one color.

3. The display panel according to claim 2, wherein the light-absorbing pattern includes a first light-absorbing sub-pattern and a second light-absorbing sub-pattern; wherein at least one color of light that the first light-absorbing sub-pattern is capable of absorbing is the same as at least one color of light that the second light-absorbing sub-pattern is capable of absorbing; or
a wavelength of the light that the first light-absorbing sub-pattern is capable of absorbing and a wavelength of the light that the second light-absorbing sub-pattern is capable of absorbing are substantially in a same range.

4. (canceled)

5. The display panel according to claim 3, wherein a material of the first light-absorbing sub-pattern is the same as a material of the second light-absorbing sub-pattern.

6. The display panel according to claim 2, wherein the light-absorbing pattern includes a first light-absorbing sub-pattern and a second light-absorbing sub-pattern, at least one color of light that the first light-absorbing sub-pattern is capable of absorbing is not exactly the same as at least one color of light that the second light-absorbing sub-pattern is capable of absorbing.

7. (canceled)

8. The display panel according to claim 2, wherein the light-absorbing pattern includes a first light-absorbing sub-pattern and a second light-absorbing sub-pattern; at least one color of light that the first light-absorbing sub-pattern in capable of absorbing is the same as or is not exactly the same as at least one color of light that the second light-absorbing sub-pattern is capable of absorbing;
the display panel further comprises:
a second heterojunction disposed between the first light-absorbing sub-pattern and the second light-absorbing sub-pattern.

9. The display panel according to claim 8, wherein the light-emitting pattern includes a first light-emitting sub-pattern and a second light-emitting sub-pattern that are sequentially arranged in the direction perpendicular to the substrate;
the display panel further comprises:
a first heterojunction disposed between the first light-emitting sub-pattern and the second light-emitting sub-pattern, wherein the first heterojunction and the second heterojunction are connected to be a one-piece structure.

10. The display panel according to claim 1, wherein the light-absorbing pattern of the photosensor is capable of absorbing light of a single color; a photosensor capable of absorbing light of a target color is arranged adjacent to a sub-pixel capable of emitting light of the target color; or
the light-absorbing pattern of the photosensor is capable of absorbing light of two colors; a photosensor capable of absorbing light of a first target color and light of a second target sub-pixel capable of emitting the light of the second target color; or
the light-absorbing pattern of the photosensor is capable of absorbing light of three colors, and the light of three colors includes red light, blue light and green light; the photosensor capable of absorbing the light of three colors is arranged adjacent to a sub-pixel capable of emitting green light.

11. (canceled)

12. (canceled)

13. The display panel according to claim 1, wherein the display panel comprises a plurality of light-absorbing patterns, wherein a material of the light-absorbing pattern includes a perovskite-based semiconductor material; light-absorbing patterns capable of absorbing light of different colors correspond to materials with different band gaps; or
the display panel comprises a plurality of light-absorbing patterns; wherein a material of the light-absorbing pattern includes a perovskite-based semiconductor material, and a molecular formula of the material of the light-absorbing pattern is RNH₃BY₃₋ₘXₘ, wherein R is CₙH₂ₙ₊₁, B is a metal element, X and Y are different halogen elements, m and n are both an integer; light-absorbing patterns capable of absorbing light of different colors correspond to materials with different band gaps, and the materials corresponding to the light-absorbing patterns capable of absorbing the light of different colors have different mass ratios of X and Y.

14. (canceled)

15. The display panel according to claim 1, further comprising:
a first light-shielding pattern disposed on a side of the second electrode layer away from the substrate, wherein the first light-shielding pattern is provided with a third opening and a fourth opening therein, and the third opening is disposed corresponding to the light-emitting pattern, the fourth opening is disposed corresponding to the light-absorbing pattern; and
a cover plate disposed on a side of the first light-shielding pattern away from the substrate;
wherein a ratio of a vertical distance from a surface of the first light-shielding pattern away from the substrate to a surface of the cover plate away from the substrate to a vertical distance from the surface of the first light-shielding pattern away from the substrate to the light-absorbing pattern is in a range of approximately 1.8 to approximately 2.8.

16. (canceled)

17. The display panel according to claim 1, further comprising:
a second light-shielding pattern disposed between the substrate and the second electrode layer, wherein the second light-shielding pattern is located between the light-absorbing pattern and a light-emitting pattern adjacent to the light-absorbing pattern, and a vertical distance from a surface of the second light-shielding pattern away from the substrate to the substrate is greater than or equal to both a vertical distance from a surface of the light-absorbing pattern away from the substrate to the substrate and a vertical distance from a surface of the light-emitting pattern away from the substrate to the substrate.

18. The display panel according to claim 1, wherein a ratio of an area of the first opening to an area of the second opening is in a range of approximately 1 to approximately 3.5; and/or
the display panel further comprises an encapsulation layer disposed on a side of the second electrode layer away from the substrate, wherein a refractive index of the encapsulation layer is in a range of 1.5 to 1.8.

19. (canceled)

20. (canceled)

21. The display panel according to claim 1, further comprising:
a circuit layer disposed between the substrate and the first electrode layer, wherein the circuit layer includes pixel circuits and at least one photosensitive driving circuit, a pixel circuit is electrically connected to the first anode, and a photosensitive driving circuit is connected to the second anode.

22. The display panel according to claim 21, wherein the circuit layer includes an active layer, a gate insulating layer, a gate conductive layer, an interlayer dielectric layer, and a source-drain conductive layer that are arranged in a direction perpendicular to the substrate and away from the substrate;
wherein the pixel circuit includes a first active layer pattern, a scan signal line and a first power supply line, the first active layer pattern is located in the active layer, the scan signal line is located in the gate conductive layer, and the first power supply line is located in the source-drain conductive layer; the pixel circuit includes at least one transistor, overlapping portions of the first active layer pattern and the scan signal line form a part of a transistor, and the at least one transistor is electrically connected to the first anode; the first power supply line is electrically connected to the at least one transistor.

23. The display panel according to claim 22, wherein the photosensitive driving circuit includes a diode and a second power supply line; the second power supply line is located in the source-drain conductive layer; an end of the diode is electrically connected to the second anode, and another end of diode is electrically connected to the second power supply line; or
the photosensitive driving circuit includes a diode and a second power supply line; the second power supply line is located in the source-drain conductive layer; an end of the diode is electrically connected to the second anode, and another end of diode is electrically connected to the second power supply line; the diode includes a second active layer pattern, and the second active layer pattern is located in the active layer; the second active layer pattern includes a first portion and a second portion that are electrically connected, the first portion is a hole-type semiconductor, and the second portion is an electron-type semiconductor; the first portion is electrically connected to the second anode, and the second portion is electrically connected to the second power supply line.

24. (canceled)

25. The display panel according to claim 1, further comprising:
a second hole transport pattern disposed between the second anode and the light-absorbing pattern; or
a second hole transport pattern disposed between the second anode and the light-absorbing pattern and a first hole transport pattern disposed between the first anode and the light-emitting pattern; wherein a material of the first hole transport pattern is different from a material of the second hole transport pattern.

26. (canceled)

27. The display panel according to claim 1, further comprising:
a first common layer disposed between the first anode and the light-emitting pattern and between the second anode and the light-absorbing pattern, wherein the first common layer includes a hole transport layer and/or a hole injection layer; and/or
a second common layer disposed between the light-emitting pattern and the second electrode layer and between the light-absorbing pattern and the second electrode layer, wherein the second common layer includes an electron transport layer and/or an electron injection layer.

28. The display panel according to claim 1, wherein the second electrode layer includes first cathodes and at least one second cathode, a first cathode corresponds in position to the light-emitting pattern, and a second cathode corresponds in position to the light-absorbing pattern;
wherein the first cathode and the second cathode are in a one-piece structure, or the first cathode and the second cathode are insulated from each other, and the first cathode and the second cathode are configured to respectively transmit different cathode signals.

29. (canceled)

30. A display panel, comprising:
a substrate;
a first electrode layer disposed on a side of the substrate, wherein the first electrode layer includes a first anode and a second anode, and the first anode and the second anode are configured to respectively transmit different anode signals;
a pixel definition layer disposed on a side of the first electrode layer away from the substrate, wherein the pixel definition layer is provided with a first opening and a second opening therein, and the first opening corresponds in position to the first anode, and the second opening corresponds in position to the second anode;
a light-emitting pattern, wherein at least portion of the light-emitting pattern is located in the first opening;
a light-absorbing pattern, wherein at least portion of the light-absorbing pattern is located in the second opening;
a second electrode layer disposed on a side of the pixel definition layer away from the first electrode layer and covering the light-emitting pattern and the light-absorbing pattern;
a first light-shielding pattern disposed on a side of the second electrode layer away from the substrate; and
a cover plate disposed on a side of the first light-shielding pattern away from the substrate;
wherein a ratio of a vertical distance from a surface of the first light-shielding pattern away from the substrate to a surface of the cover plate away from the substrate to a vertical distance from the surface of the first light-shielding pattern away from the substrate to the light-absorbing pattern is in a range of approximately 1.8 to approximately 2.8.

31. A display apparatus, comprising:
the display panel according to claim 1; and
a housing disposed at least partially around the display panel.
